(19) United States
(12) Patent Application Publication
(10) Pub. No.: US 2020/0131632 A1
(43) Pub. Date: Apr. 30, 2020

(54) Plasma Resistant Multi-Layer Coatings and Related Methods of Preparing Same

(71) Applicant: Greene, Tweed Technologies, Inc., Wilmington, DE (US)

(72) Inventors: Alexandru Pavel, Wayne, PA (US); Vasil Vorsa, Coopersburg, PA (US)

(21) Appl. No.: 16/664,266

(22) Filed: Oct. 25, 2019

Related U.S. Application Data
(60) Provisional application No. 62/750,628, filed on Oct. 25, 2018.

(51) Int. Cl. C23C 16/455; C23C 16/40; C23C 16/04

(52) U.S. Cl. CPC C23C 16/45529; C23C 16/45525; C23C 16/45555; C23C 16/405; C23C 16/045; C23C 16/403

(57) ABSTRACT

The present invention relates to a method of providing a multi-layer coating to a surface of a substrate, a multi-layer coating prepared by the method and a component comprising the multi-layer coating. The present invention also relates to a method of suppressing or inhibiting growth of a certain phases and/or structures of a crystalline structure with an amorphous first metal oxide coating and a substrate having a surface bearing the coating.

### CROSS REFERENCE TO RELATED APPLICATION

This application claims the benefit under 35 U.S.C. § 119(e) of U.S. Provisional Patent Application Ser. No.62/750,628, filed Oct. 25, 2018, entitled, “Plasma Resistant Multi-Layer Coatings and Methods of Preparing Same,” the entire disclosure of which is incorporated herein by reference.

### BACKGROUND OF THE INVENTION

To prevent contamination of semiconductor wafers, semiconductor manufacturing equipment and flat panel display manufacturing equipment made of high purity materials with low plasma erosion properties. During manufacturing, these materials are exposed to highly corrosive gases, particularly halogen-based corrosive gases such as fluorine and chorine-based gases. Materials in the processing equipment are required to have a high resistance to erosion. To address this need, ceramics coatings such as alumina and yttria have been applied. The most frequently used method in semiconductor technology to apply these coatings is thermal spray and all its variations. However, even these materials erode over leading to lower yield and costly down time.

Thus, there is a need for coatings with improved resistance to erosion. There is now emerging plasma-resistant coatings deposited by ALD. Advantages of ALD include conformal, dense, and pinhole-free film that have the ability to coat complex 3D shapes and high-aspect ratio holes. The inventions described herein address a further improvement over current plasma-resistant coating and films and may be prepared using an atomic layer deposition process.

### BRIEF SUMMARY OF THE INVENTION

The invention described herein includes high performance multi-layer coatings, and methods of depositing such coatings, and components and equipment that bears such coatings.

While much of the description provided herein addresses use of the coatings in the semiconductor processing arena (e.g., where the coatings are exposed to plasma gases), it is contemplated that the methods and coatings of the invention can be used advantageously in any end application that involves high temperature and/or corrosive environments and related uses. Examples include without limitation, microchip device fabrication for transistor components (gate oxide, metal gate, etc.) and memory components, laminates for barrier layer applications in anti-corrosion, thermal protection, electrical insulator layers, hydrophobic surfaces, etc, electroactive layers for architectural coatings on large planar glass substrates, photovoltaic solar cell layers with defined functional roles, rechargeable batteries layered cathodes and electrolyte layers, solid oxide fuel cell membranes, optical coatings, biocompatible layers for implants, sensors and detectors with layered structure, 2-D layers with specific functional roles, planar junctions, bi-, and multi-component heterogeneous catalysts.

The invention includes a methods of providing a multi-layer coating to a surface of a substrate that includes forming an anchor layer by controlled oxidation of the surface of the substrate (Me¹Oxide); depositing on the anchor layer a glue layer comprising an amorphous or crystalline first metal oxide (Me¹Oxide); forming on the glue layer a graded laminate layer containing the first metal oxide (Me¹Oxide) and a second metal oxide (Me²Oxide), and having a gradient with an increasing content of the second metal oxide (Me²Oxide) and a decreasing content of the first metal oxide (Me¹Oxide) such that a lowermost stratum of the graded laminate layer immediately adjacent to the glue layer contains no more than about 0.1 mol % to about 49 mol % of the second metal oxide (Me²Oxide) and an uppermost stratum of the graded laminate layer immediately adjacent to an external layer contains no more than about 0.1 mol % to about 49 mol % of the first metal oxide (Me¹Oxide); and depositing on the graded laminate layer the external layer comprising the second metal oxide (Me²Oxide).

In an embodiment, each of the anchor layer, the glue layer, the graded laminate layer and/or the external layer may be independently formed and/or deposited using an atomic layer deposition process.

Also included are methods of using the concept described above for suppressing, inhibiting, or eliminating growth of certain crystalline phases and/or structures oxides, using an interrupt layer.

The interrupt layer may contain at least two or at least three sublayers deposited sequentially, one upon the next, using an atomic layer deposition process: i) a first interrupt sublayer that is a graded laminate sublayer containing Me¹Oxide and Me²Oxide, wherein the first graded laminate sublayer has a gradient with an increasing content of the first metal oxide (Me¹Oxide) and a decreasing content of the second metal oxide (Me²Oxide) such that a lowermost stratum of the first graded layer immediately adjacent to the second metal oxide Me²Oxide coating layer contains no more than about 0.1 mol % to about 49 mol % of the first metal oxide (Me¹Oxide) and an uppermost stratum of the first graded layer immediately adjacent to a second sublayer contains no more than about 0.1 mol % to about 49 mol % of the second metal oxide (Me²Oxide); ii) a second interrupt sublayer containing Me¹Oxide in an amount of about 100 mol %; and iii) a third interrupt sublayer that is a graded laminate layer containing Me¹Oxide and Me²Oxide wherein the second graded laminate sublayer has a gradient with an increasing content of the second metal oxide (Me²Oxide) and a decreasing content of the first metal oxide (Me¹Oxide) such that a lowermost stratum of the interrupt layer immediately adjacent to the second sublayer layer contains no more than about 0.1 mol % to about 49 mol % of the second metal oxide (Me²Oxide) and an uppermost stratum of the interrupt layer immediately adjacent to a second Me²Oxide coating layer contains no more than about 0.1 mol % to about 49 mol % of the first metal oxide (Me¹Oxide); and depositing on the interrupt layer a second Me²Oxide coating layer containing Me²Oxide in an amount of about 100 mol % using an atomic layer deposition process to a thickness of 1-1000 nm. If the interrupt layer contains only two sublayers, the middle layer is omitted. Further, in some embodiments, more than one interrupt layer may be present.

### BRIEF DESCRIPTION OF THE SEVERAL VIEWS OF THE DRAWINGS

At least one drawing or image executed in color and/or a photograph is included herein. Copies of this patent or patent application publication with color drawings and photographs will be provided by the Office upon request and payment of the necessary fee.

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one. In the drawings:

FIG. 1 is a schematic cross-sectional view of a substrate bearing the multiplayer coating of the invention;

FIG. 2 is an overview of the process steps of an embodiment of the invention;

FIG. 3 is schematic cross-sectional view of a substrate surface bearing contamination;

FIG. 4 is a general overview of one cycle of an atomic layer deposition process;

FIG. 5 is a cartoon view of one cycle of an atomic layer deposition process at the molecular level;

FIG. 6 is a table listing exemplary metal and non-metal precursors that may be used in various combinations to deposit any of the layers or sublayers of the invention in an atomic layer deposition process;

FIG. 7 is a cross sectional view of an embodiment of an multi-layer coating of the invention;

FIG. 8 is a cross sectional view of a portion of the multilayer coating of the invention illustrating a gradient present in the graded laminate layer of embodiment of the multi-layer coating of the invention;

FIG. 9 is an ‘exploded’ view of the sublayers making up a compositionally binary stratum of the graded laminate layer in a first embodiment of the process;

FIG. 10 is a graphical representation of the two graded laminate layers between layers of 100% yttria and 100% alumina;

FIG. 11 is an exploded view of homogenous sublayers making up a stratum of the graded laminate layer in a second embodiment of the process;

FIG. 12 is a cross sectional view of a metal oxide coating containing an interrupt layer in accordance with the invention;

FIG. 13 is a linear representation of potential gradient schemes for the graded laminate layer(s) in accordance with the invention;

FIG. 14 is a representation of an alternative embodiment of the invention where the inventive process has been applied to prepare a repeating scheme of alternating layers of one oxide upon a second oxide;

FIG. 15 is a graphical representation of the compositional structure of an embodiment of the invention using a two-component composition for the layer;

FIG. 16 is a graphical representation of the compositional structure of another embodiment of the invention, also using a two-component composition for the layer;

FIG. 17 is a graphical representation of the compositional structure of an embodiment of the invention including interrupt layers;

FIG. 18 is a representation of exemplary ordered sequences of the compositional gradient blocks included in the invention when the blocks include three or four components;

FIG. 19 is a micrograph showing a cross section of an exemplary anchor layer developed in the practice of the method of the invention; the layer was developed by controlled oxidation of the aluminum substrate surface upon exposure to ozone at a high temperature;

FIG. 20 is a micrograph showing a cross section of an exemplary coating of the invention on a silicon substrate. In this example, the coating is made up of two layers, each of a repeating four block unit and is capped with a pure Y₂O₃ block.

FIG. 21 shows a cross section of EDS line scan data of elemental aluminum and yttrium as a function of the position with the layer of the invention;

FIG. 22 is a micrograph prepared by transmission electron microscopy (TEM) of an exemplary coating of the invention with its EDS line scan data overlaid;

FIG. 23 a “zoomed in” versions of the TEM cross section micrograph of FIG. 22 (without substrate);

FIG. 24 is the micrograph of FIG. 23 with the EDS line scan overlaid;

FIG. 25A is an EDS “color map” of the cross-sectional micrograph showing an exemplary coating where the transitioning CGL interlayers appear as relatively discrete orange bands;

FIG. 25B is an EDS “color map” of the cross-sectional micrograph showing an exemplary coating where the transitioning CGL interlayers, i.e., interrupt layers, appear as “fuzzy” orange bands;

FIG. 26 is a micrograph of a cross section of an exemplary coating of the invention;

FIG. 27 is a micrograph of a cross section of a coating formed for comparison of Y₂O₃ without the interrupt layers;

FIG. 28 is a table showing data obtained from scratch adhesion testing of an exemplary coating of the invention and of a coating prepared with no interrupt layers;

FIG. 29 is a bar graph comparing occurrences of side cracking and major failures of each of an exemplary coating of the invention (darker bars) and a coating prepared without the interrupt layers (solid bars);

FIG. 30 is a TEM micrograph of a cross section of a coating of the invention on substrate; and

FIG. 31 is a “blow up” of a portion of the cross-sectioned coating of FIG. 30.

### DETAILED DESCRIPTION OF THE INVENTION

The invention described herein include methods of providing a multi-layer coating to a surface of a substrate, substrates and/or articles coated or provided with such films, including for example, semiconductor processing components and equipment. Also included are related methods of reducing disruptive forces present at an interface between two metal oxide layers and methods of inhibiting unwanted crystalline growth (e.g. columnar) and/or a crystalline phase in an atomic layer deposition process.

The invention as described herein allows for preparation of a plasma resistant multi-layer coating that exhibits excellent bonding of the film to a substrate by virtue of a series of layers of varying materials that create a gradual chemical transition. In addition, in some embodiments, the presence of the graded laminate layer as described infra allows for greater film adhesion and resistance to partial etching of the multi-layer coating over time when used on semiconductor process equipment piece and renders any post-deposition annealing step for layer inter-diffusion purposes obsolete. It therefore permits creation of crystalline films with highly controlled structure or amorphous films with a high degree of homogeneity or even perfectly homogeneous amorphous films.

In other embodiments, the multi-layer coatings and processes of the invention may be used to prepare and/or to coat substrates that form components useful in a variety of industries, especially those where components may be exposed to high temperatures, and/or corrosive chemicals. For example, the multi-layer coatings of the invention may be used on components that are found in equipment/machines/devices used in aerospace, pharmaceutical production, food processing, oil field applications, military and/or maritime applications, industrial manufacturing, and scientific and/or diagnostic instrumentation.

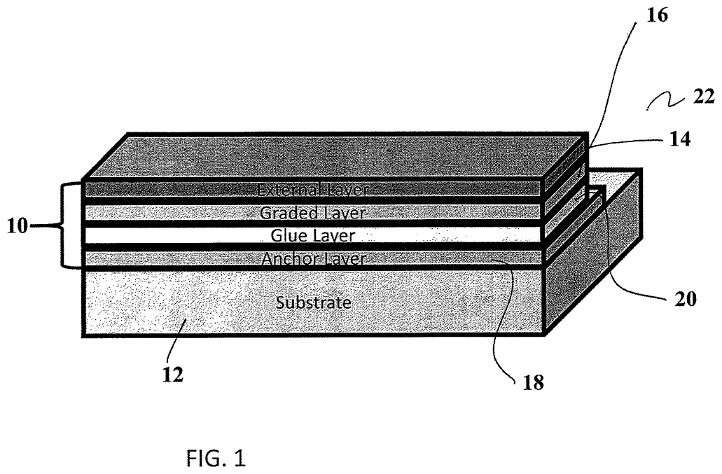

With reference to FIG. 1, a coated substrate 22 includes a substrate 12 having a multi-layer coating 10. Each layer of the multi-layer coating 10 is deposited, one upon the other, so the coating extends axially from the substrate in the direction of coating growth.

The substrate 10 may be any material useful for the desired end applications. In some embodiments, one may prefer that the substrate is a non-ferrous metal, a non-ferrous metal alloy, a ferrous metal or a ferrous metal alloy. Suitable materials may include substrates of titanium, aluminum, nickel, ceramics, aluminum alloys, steels, stainless steel, carbon steel, alloy steel, copper, copper alloys, lead, lead alloys, ceramics, quartz, silicon, a glass, a polymer, such as a high performance polymer, and a fiberglass. The substrate may also combine materials, that is, a portion may be, for example, made of aluminum and an adjacent portion made of copper.

The coated substrate may make up or be part of a variety of components, such as, for example, components that are planar in nature or have a 3D geometry. For example, the component may be a chamber component, like a shower head, a chamber wall, a nozzle a plasma generation unit, a diffuser, a gas line interior, a chamber orifice, and the like.

The multi-layered coating 10 may include an anchor layer 18 that is adjacent to the substrate 12. When the substrate 12 selected is a metal, the anchor layer 18 is an oxide of the metal created by a controlled oxidation process carried out at the surface of the substrate. For example, if the substrate is aluminum, the anchor layer may be made up of Al₂O₃, AlOₓ, and/or mixtures of the same, developed at surface by controlled anodization. The anchor layer oxide may be developed by exposing the clean substrate surface to ozone, O₂, O₂ plasmas, H₂O₂, N₂O, NO₂, NO, and mixtures of the same. The anchor layer oxide may be developed in-situ or ex-situ the ALD chamber by exposing the substrate surface to ozone, O₂, O₂ plasmas, H₂O₂, N₂O, NO₂, NO, acid attack or electrolytic/electroless anodization. The anchor layer provides linkage via chemical (not physical) bonding to the substrate and the remainder of the coating layer.

Development of the oxide to form the anchor layer may be carried out by a variety of processes well known in the art and generally at temperatures of about 21° C. to about 800° C. If the remaining layers of the multi-layer coating are to be deposited via an atomic layer deposition process (“ALD Process”), the step of developing the anchor layer may be carried out in the ALD tool using the established protocols of the specific tool.

In most embodiments, it may be preferred that the anchor layer 18 is as uniform and continuous along the entire surface of the substrate as is possible. In general, the thickness of the anchor layer may vary, depending on the end application of the coated substrate and/or the overall intended thickness of the multi-layer coating. In many embodiments, the anchor layer has a thickness of about 0.1 to about 100 nanometers; of about 1 to about 50 nanometers; of about 5 to about 35 nanometers and of about 10 to about 20 nanometers. In embodiments, the layer may be up to 1 micron or more, e.g., in some instances up to several hundred microns.

In embodiments where the selected substrate is non-metallic, e.g., quartz, polymer, glass, and the like, the anchor layer 18 may be omitted from the multi-layered coating of the invention.

On top of the anchor layer, if present, the multi-layered coating may include a glue layer 20 that is made of a first metal oxide in an amorphous or crystalline state, followed by a graded laminate, and an external layer. The graded laminates, for reasons explained in more detail infra, provide a controlled gradual change in composition from the metal oxide surface of the glue layer to the external layer resulting in increased adherence and durability of the coating overall. The external layer, in a finished product, is exposed to an environment such as the interior of a reaction or etching chamber and is resistant to degradation by plasmas. In a preferred embodiment, each of the glue layer, the graded laminate layer and the external layer are deposited using an ALD process. Such processes can be carried out using commercially available ALD tools, process protocols and chemical precursors (metal and non-metal), such as, for example, those available from Picosun (P-series and R-series ALD systems); Beneq Oy (TFS-series or P-series) Oxford Instruments (FlexAl and OpalAl ALD systems); and/or Veeco Instruments (Savannah, Fiji, and Phoenix ALD systems).

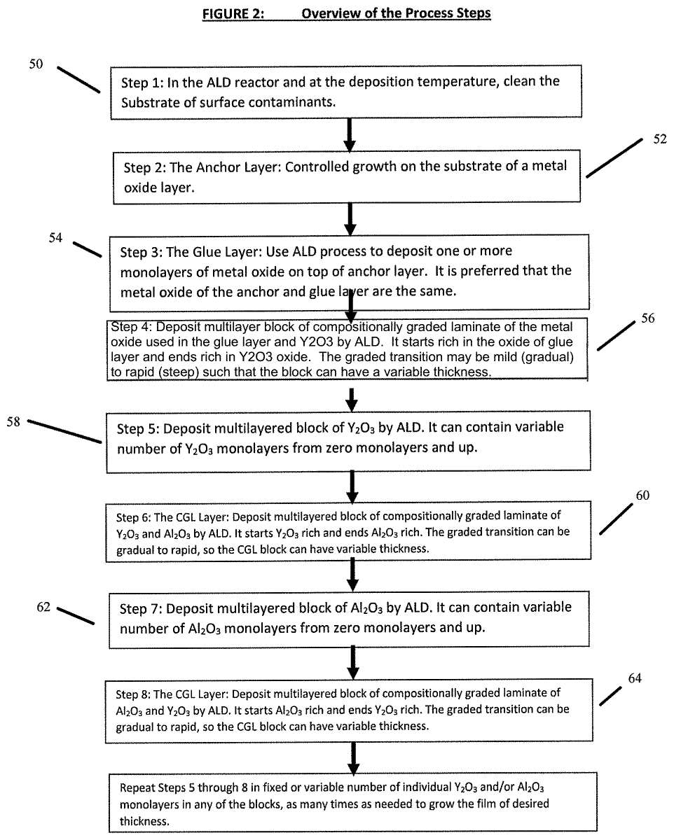

FIG. 2 provides an overview of the process steps in one embodiment included in the preparation of the multi-layer coating of the invention.

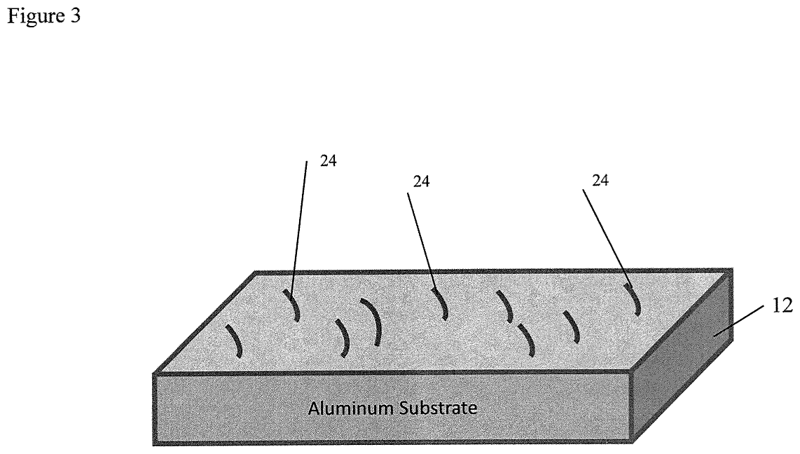

In an embodiment, to prepare a multi-layer coating of the invention, one selects a substrate as described above. Referencing the FIG. 3, if the substrate is a metal substrate, any irregular passivation and/or contamination 24 on the surface of the substrate should be removed. This may be accomplished by any means known in the art, for example, by exposing the surface of the substrate to ozone in a reaction space, such as the chamber of an ALD tool. See, FIG. 2, box 50. In a version of the process, it may be preferred that this step is carried out at the deposition temperature, for example, about 21° C. to about 800° C.

The cleaned substrate is then treated so that an anchor layer of metal oxide is grown on the surface. This may be accomplished by exposure to ozone, O₂, O₂ plasmas (precursor H₂O), H₂O₂, N₂O, NO₂, NO, and mixtures of the same which provides for a controlled formation of a metal oxide on the surface of the substrate. The metal oxide forms depends on the constituent of the substrate; an aluminum substrate develops an anchor layer of aluminum oxide; a titanium substrate develops an anchor layer of titanium oxide, etc. See, FIG. 2, box 52.

Using an ALD process, a glue layer is deposited on the anchor layer. See, FIG. 2, box 54. The glue layer is made up on a metal oxide, preferably a metal oxide that is the same or is highly compatible from a point of view of chemical reactivity, strong bonding, crystalline phase type, etc. with the metal oxide of the anchor layer. The metal oxide will vary; its selection will be influenced by various factors, including the nature and chemical composition of the substrate and/or anchor layer (if present). For purposes of illustration, examples may include oxides of yttrium, rare earth metals, transitional metals like titanium, hafnium, zirconium, tantalum, metalloids (including silicon), metals of the main groups and mixtures of the same. Some examples include alumina, aluminum, Al₂O₃, Y₂O₃, La₂O₃, HfO₂, Ta₂O₅, Er₂O, ZrO₂, Y₃Al₅O₁₂ (YAG), Er₃Al₅O₁₃ (EAG), Y₄Al₂O₉ (YAM), YAlO₃ (YAP), Er₄Al₂O₉ (EAM), ErAlO₃ (EAP) and mixtures thereof. As used herein, “rare earth metals” include yttrium and scandium.

As is known to a person of skill in the art, a layer formed by ALD is made up of one or more monolayers of a metal oxide, where each monolayer is laid down by one reaction cycle carried out within the ALD tool chamber. The glue layer of the invention may be composed of any number of monolayers desired. The number of monolayers will necessarily vary depending on the thickness one wishes to be in the end application. It may be preferred that the glue layer is composed of about 1 or 2 to about 1000 monolayers, about 100 to 700 monolayers and/or about 300 to about 500 monolayers.

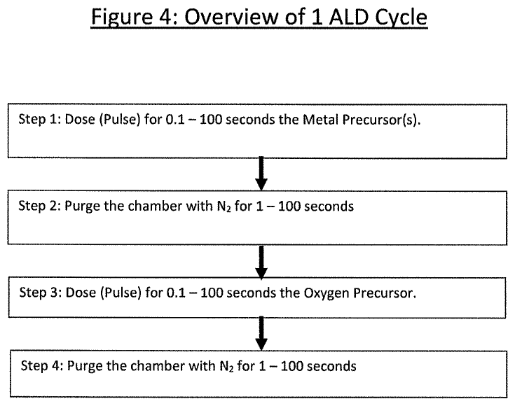

By way of example, FIG. 4 is a general illustration of one ALD cycle which results in one monolayer as is used for the deposition of the glue layer, graded laminate layer and external layer described herein. First, the substrate is placed in the ALD reaction chamber and exposed to the selected metal precursor for 0.1 to 100 seconds to allow chemisorption of the precursor to the substrate (or previous monolayer). The chamber is then purged of precursor, usually using N₂ (for about 1 to about 100 seconds). An oxygen precursor (such as an H₂O₂, O₂, O₂ plasma, O₃, H₂O₂, N₂O, NO₂, NO or a combination thereof is placed in the chamber and reacts with the metal precursor to form a monolayer. When this reaction is completed (usually within about 0.1 to 100 seconds), the chamber is purged of leftover precursor and unwanted reaction products, usually with N₂ for about 1 to 100 seconds.

It is noted that the dose and purge times given above in ranges are merely illustrative. It is well within the skillset of a person of ordinary skill in the art to determine dose time and purges times for an ALD process. As in known in the art, ALD reactions are self-limiting. The ALD reaction must have optimized dosing concentrations and times plus optimized purge times for each of the precursors.

In various embodiments, either both of the purge steps can be accomplished using argon, or any other inert gas(es) in place of or mixed with nitrogen.

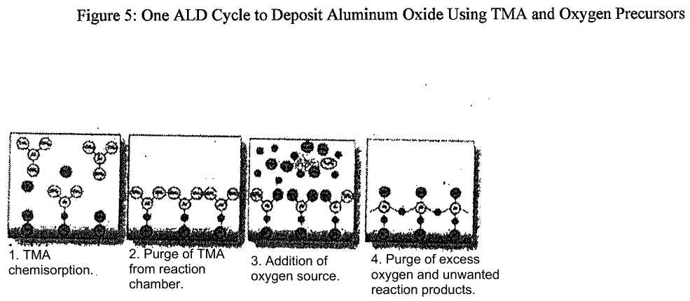

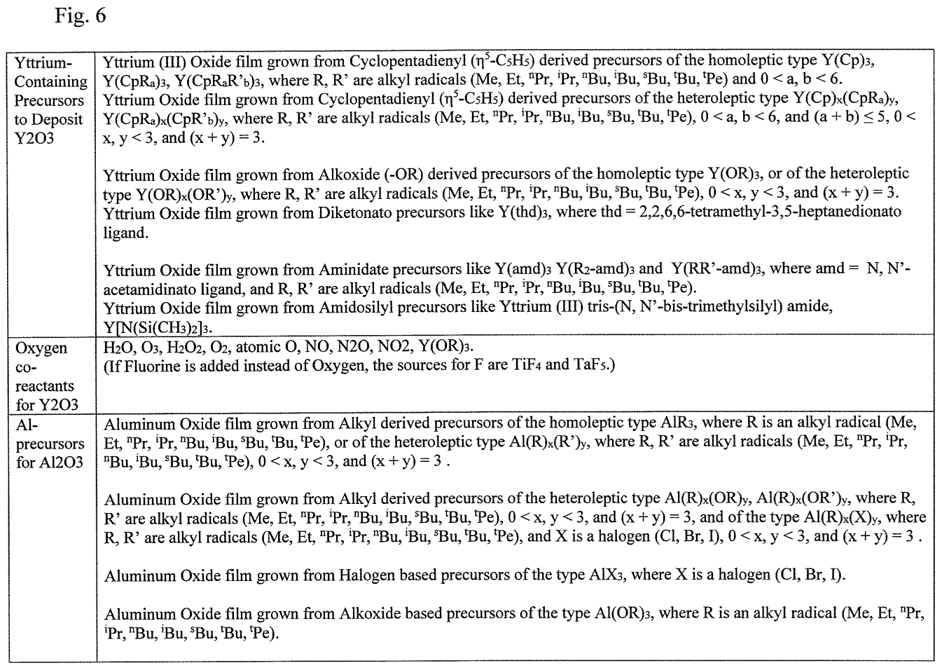

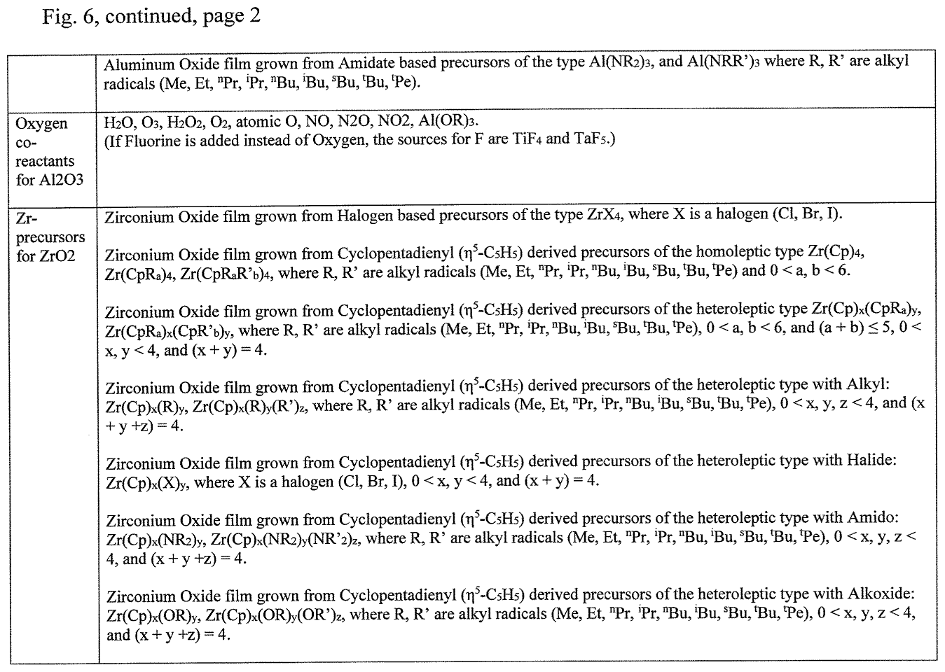

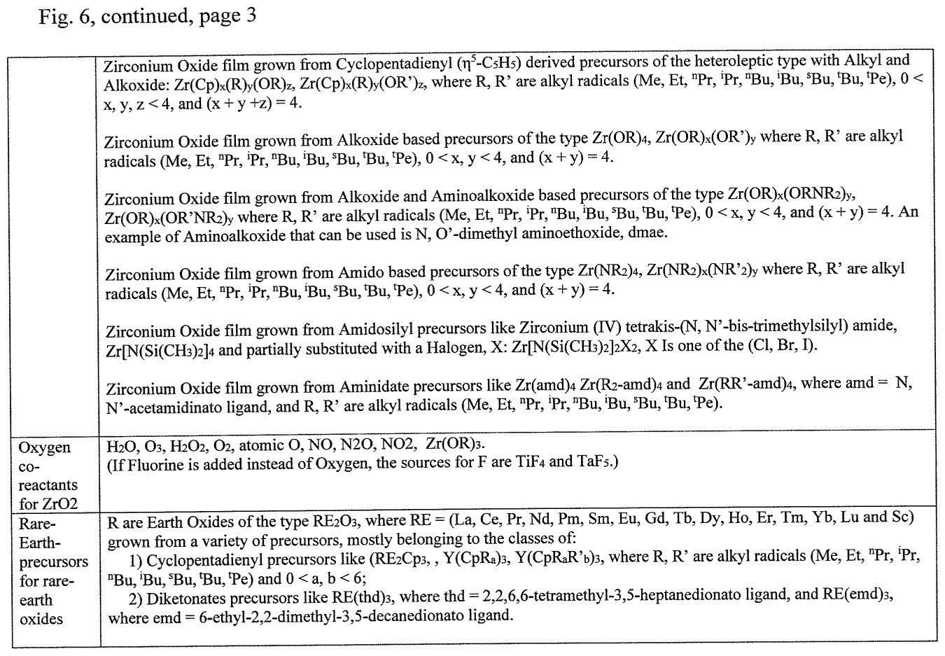

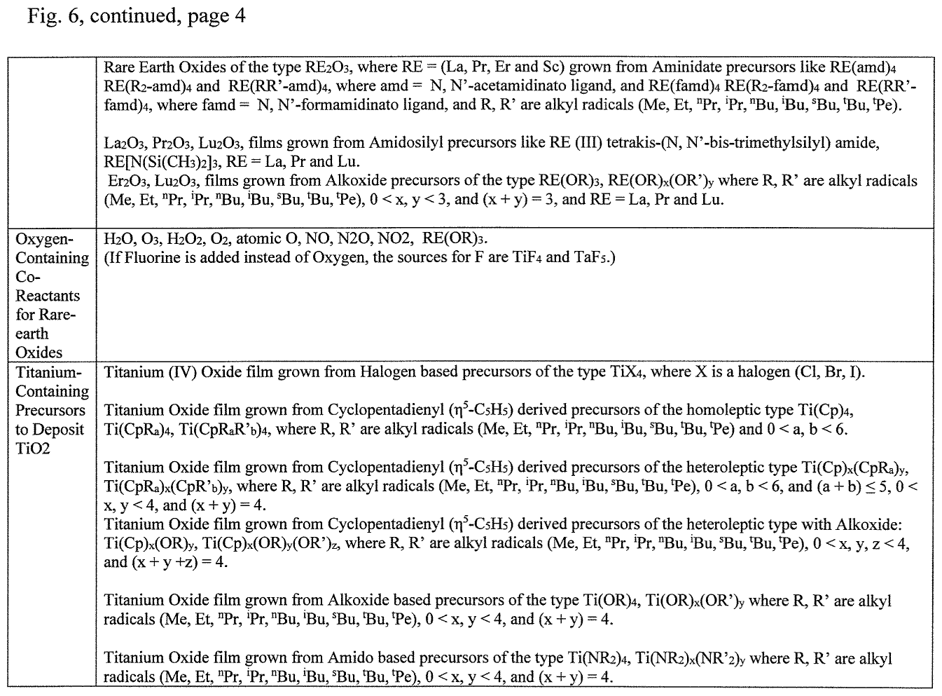

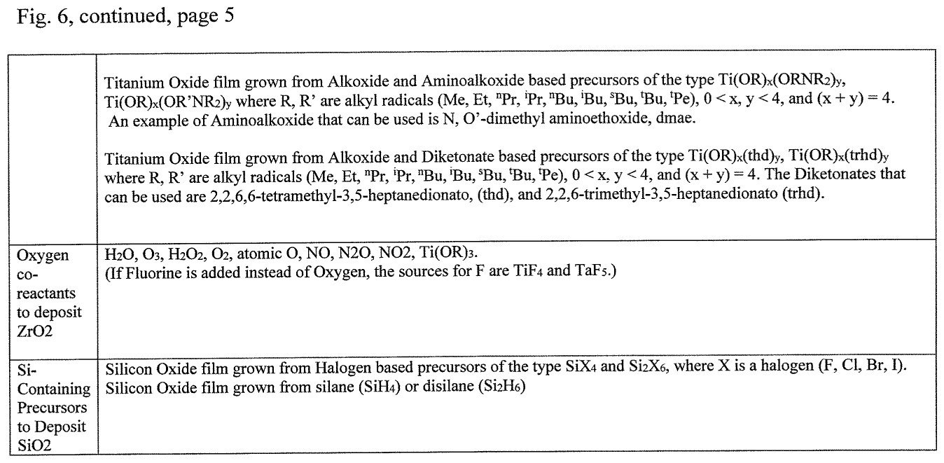

FIG. 5 is illustrative of this process at the atomic level (using an aluminum substrate and the metal precursor trimethyl aluminum (‘TMA”)). Other options for precursors can be selected from those exemplary non-limiting precursors set out in the table of FIG. 6. Such precursors and combinations of them are suitable for use in the ALD process described throughout for deposition of the glue layer, the grade layer and the external layer.

The thickness of the glue layer may be variable and may in some embodiments, be up to an including about a micron in thickness. In some embodiments, it may be preferred that the thickness is 0.1 to about 100 nanometers, about 1 to about 50 nanometers, about 5 to about 35 nanometers and about 10 to about 20 nanometers.

Once the glue layer has been formed to desired thickness, a graded laminate layer is deposited. See, FIG. 2, box 56. The graded laminate layer is designed to be a transition layer between the metal oxide of the glue layer and the second metal oxide (Me²Oxide), providing a gradual change in composition from the metal oxide on the surface of the substrate to the external, plasmas resistant coating, thus eliminating abrupt changes in composition at the interface of the metal oxide layers. The presence of the graded laminate layer allows for a smooth transition between a glue layer of a first metal oxide (e.g., alumina or AlOx) to the external layer that contains a second metal oxide (e.g., Y₂O₃), easing the disruptive forces that exist at the interface of such a design. In addition, one may tailor the graded laminate layer to be a gradual transition or to be a rapid transition between the differing metal oxide layers for different end properties.

It is hypothesized that the presence of the graded laminate layer allows for greater resistance to partial etching of the external layer when in use over time. This resistance can be in the form of lower etch rate and/or more durable film (for example, reduced potential for film delamination). Another advantage of the presence of the graded laminate layer is that it makes the post-deposition annealing step of the coating obsolete and thus may yield amorphous films with a high degree of homogeneity or potentially perfectly homogeneous amorphous films. The graded laminate layer in combination with the anchor layer also provides for excellent bonding of the plasma-resistant film to the substrate.

In general terms, the graded laminate layer is compositionally constructed so that adjacent to the glue layer, the graded laminate layer is rich in the metal oxide of the glue layer and poor in the oxide of the external layer. Conversely, the portion of the graded laminate layer that is adjacent to the external layer is rich in the metal oxide of the external layer, but poor in the metal oxide of the glue layer, that is, the graded laminate layer included both a first metal oxide and a second metal oxide and has an increasing content of the second metal oxide and a decreasing content of the first metal oxide as it transitions towards the external layer, which is composed of the second metal oxide. This is illustrated schematically below, where Me¹ and Me² each represent a different metal, such as for example, titanium, aluminum, and/or yttrium:

External Layer of Me²Oxide
Me²Oxide > Me¹Oxide
Me¹Oxide > Me²Oxide
Glue layer of Me¹Oxide
Anchor Layer (may be Me¹Oxide)

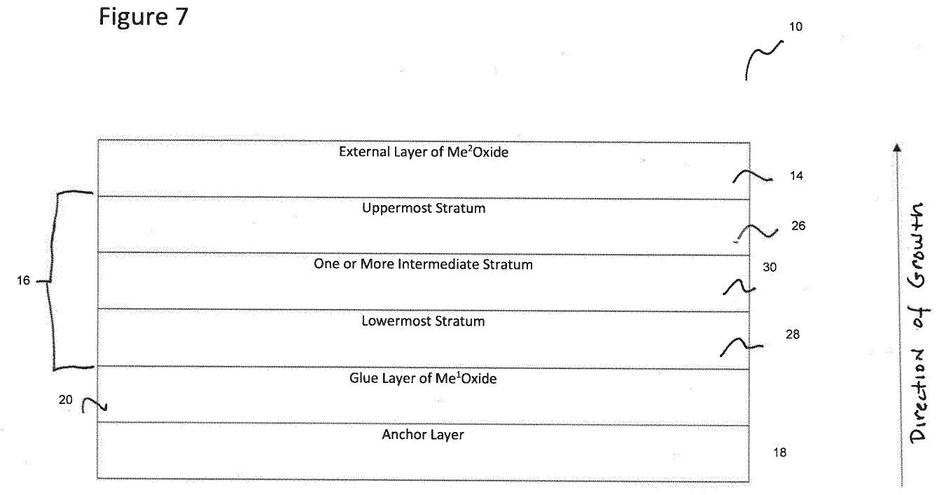

Accordingly, with reference to the schematic above and to FIG. 7, to create this compositional gradient, a lowermost stratum 28 of the graded laminate layer that is immediately adjacent to the glue layer 20 may contain, in various embodiments, about 0.1 mol % to about 49 mol % of the second metal oxide, about 5 mol % to about 40 mol %, about 10 mol % to about 30 mol % and/or about 15 mol % to about 20 mol % of the second oxide. Conversely, the uppermost stratum 26 of the graded laminate layer immediately adjacent to an external layer 14 may contain, in various embodiments, about 0.1 mol % to about 49 mol % of the second metal oxide, about 5 mol % to about 40 mol %, about 10 mol % to about 30 mol % and/or about 15 mol % to about 20 mol % of the first oxide.

The “uppermost stratum” and the “lowermost stratum” may be independently composed of any number of monolayers. In most embodiments, the “uppermost stratum” and the “lowermost stratum” are independently each composed of about 1 to about 500 monolayers, preferably about 50 to 100 monolayers wherein each monolayer is formed by one cycle of an ALD process.

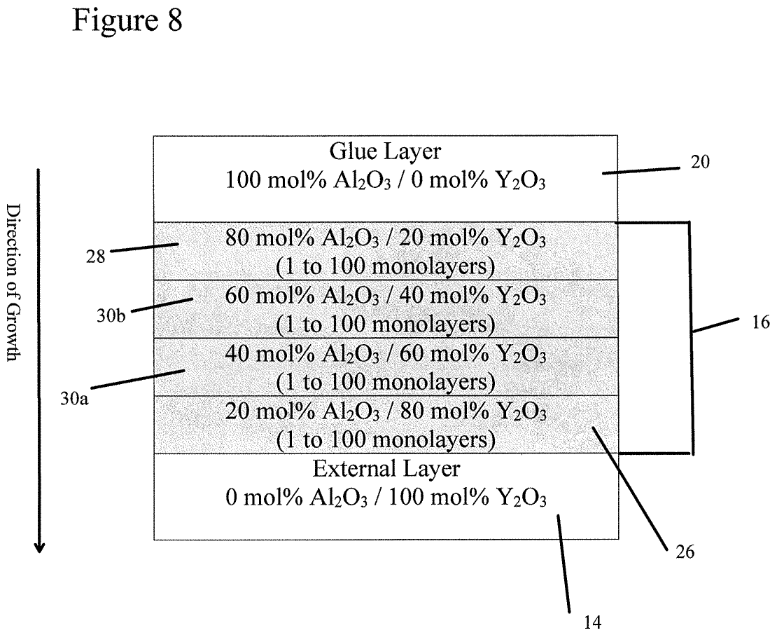

Latitudinal symmetry of the graded laminate layer 16 may be desired in some embodiments, but is not required; that is, for example, with reference to the cross sectional view presented in FIG. 8, the uppermost stratum 26 may contain 80 mol % Me²Oxide and 20 mol % Me¹Oxide and be composed of 50 monolayers, and the lowermost stratum 28 may contain 80 mol % Me¹Oxide and 20 mol % Me²Oxide and be composed of 10 monolayers.

Referencing FIG. 8, in many embodiments that may be preferred, that one or more intermediate strata 30 are disposed between the uppermost stratum 26 and the lowermost stratum 28, each having a different compositional gradient such that overall compositional structure of the graded laminate layer 16 increases in content of the oxide of the external layer 14 (Me²Oxide) and decreases in content of the oxide of the glue layer 20 (Me¹Oxide) as one progress in the direction of the external layer 14, which is composed of Me²Oxide. If intermediate strata are present, each may be independently composed of about 1 to about 1500 monolayers, preferably about 50 to 100 monolayers or 100 to about 500 monolayers.

The one or more intermediate strata may each individually contain any mole ratio of the Me¹Oxide to the Me²Oxide, so long as the overall compositional gradient structure of the graded laminate layer is maintained. Variation of the ratio of the oxides among the layers permits preparation of grade layers having steep transitions, gradual transitions and/or intermediate tractions.

FIG. 8 provides a schematic representation of an illustrative example. As shown therein, a graded laminate layer 16 may be prepared to transition between a glue layer 20 of 100 mol % AlOₓ and an external layer 14 of 100 mol % Y₂O₃. The graded laminate layer 16 is composed of an uppermost stratum 26, and lowermost stratum 28 and two intermediate strata 30a and 30b (each of, for example, having 1-100 monolayers) which gradually increase in composition of Y₂O₃ as they progress towards the external layer 14.

In the example of FIG. 8, the lowermost stratum 28 contains the oxides in a ratio of 80 mol % Al₂O₃/20 mol % Y₂O₃, the first intermediate stratum 30a contains the oxides in a ratio of 60 mol % Al₂O₃/40 mol % Y₂O₃; the second intermediate stratum 30b contains the oxides in a ratio of 40 mol % Al₂O₃/60 mol % Y₂O₃, and the uppermost stratum 26 contains the oxides in a ratio of 20 mol % Al₂O₃/80 mol % Y₂O₃.

Each stratum may be prepared by any means in the art, although various atomic layer deposition processes may be preferred.

In an exemplary method, each strata is prepared by depositing sequential sublayers, each sublayer containing 100% of the first oxide or the second oxide, where X is the number of sublayers of Me¹Oxide and Y is the number of sublayers of Me²Oxide, and the ratio of X to Y is representative of the ratio of Me¹Oxide:Me²Oxide (by % mol) desired in the specific stratum. When the various strata are assembled together, this provides for a compositionally binary stratum which nonetheless maintains the desired ratio of metal oxides.

In many embodiments, it is preferred that X and Y are divided by a common denominator, preferably the largest common denominator, to reduce the number of sublayers one needs to prepare while maintaining the desired overall Me¹Oxide:Me²Oxide ratio in the stratum. For example, if a 70:30 ratio is targeted, one could deposit 70 sublayers of a first oxide and 30 sublayers of a second oxide, but, in most embodiments, one may prefer to deposit 7 sublayers of a first oxide and 3 sublayers of a second oxide; either option maintains the overall desired molar ratio of the stratum.

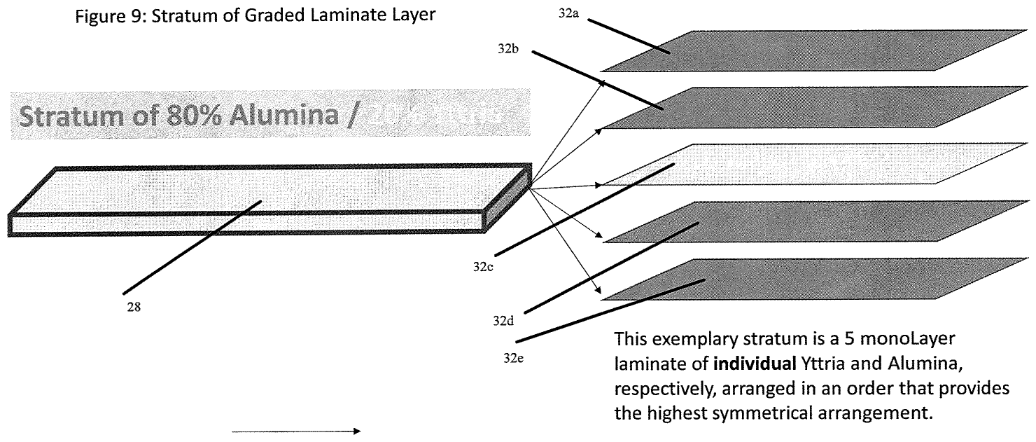

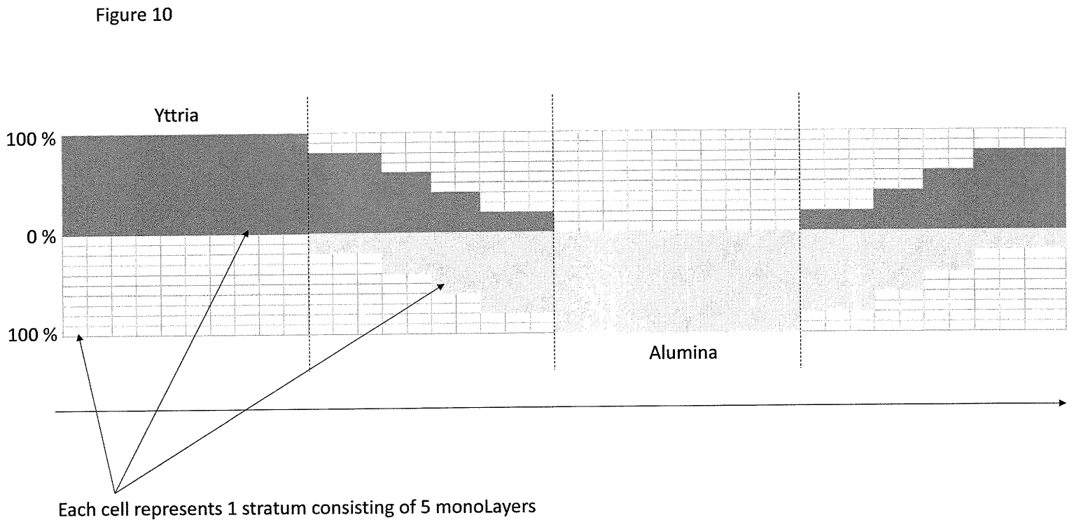

In another similar example, to prepare the lowermost stratum 28 of FIG. 9 which contains the oxides in a ratio of 80 mol % AlOₓ/20 mol % Y₂O₃, where X=80; Y=20, one forms the stratum by depositing 4 sublayers of 100 mol % AlOₓ (because 80/20=4) and 1 sublayer of 100 mol % Y₂O₃ (because 20/20=1), as is shown in FIG. 10. In FIG. 9, the lowermost stratum 28 is shown in an exploded view, where five sublayers, 32a-d are illustrated. Sublayers 32a, 32b, 32d, and 32e are each composed of 100 mol % alumina and sublayer 32c is composed of 100% yttria, giving the overall stratum a composition of the desired ratio of 80 mol % AlOₓ/20 mol % Y₂O₃.

In preferred embodiments, the sublayers of the strata are deposited in an order that provides the greatest symmetrical arrangement of the sublayers within the overall strata. Referencing FIG. 9, the yttria sublayer 32c is sandwiched between sublayers 32a and b and sublayers 32d and e. In the previous example describing depositing 10 sublayers to achieve a 70 mol %/30 mol % ratio, the greatest symmetry is provided by the layering arrangement:
-A/A/B/A/A/B/A/A/B/A/-
   where A is the oxide present in 70 mol % and B is the oxide present in 30 mol % in the stratum.

This arrangement presents the greatest symmetry, even though there are an odd number of “A” layers present.

FIG. 10 schematically illustrates a graded laminate layer between and adjacent to each of the glue layer of 100% yttria and the external layer of 100% alumina. The graded laminate layer has a gradual composition gradient represented by the different colored cells. In this Figure, each cell represents one stratum consisting of five monolayers.

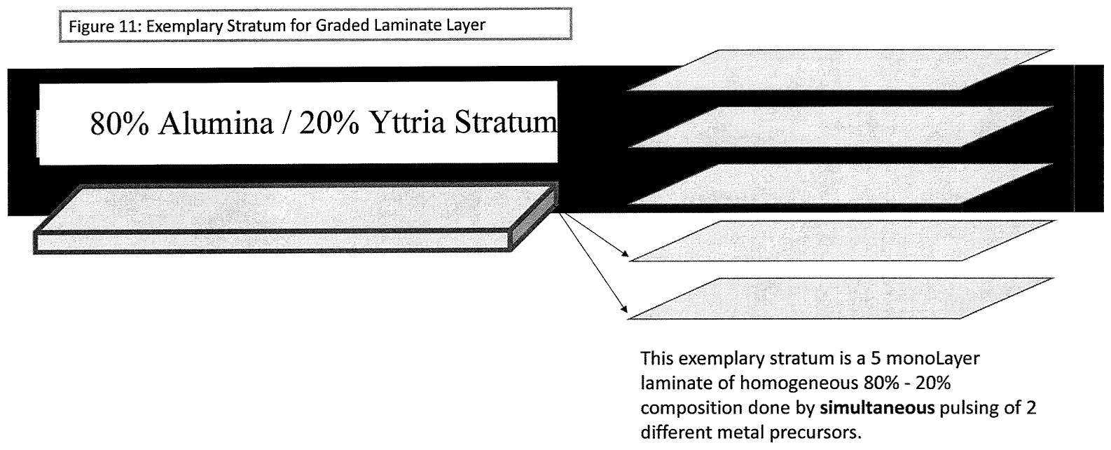

In an alternative embodiment, instead of creating compositional binary film a by alternating deposition of metal oxides, the sublayers of each strata can be created by co-depositing two metal precursors simultaneously into the reaction chamber so that the Me¹Oxide and Me²Oxide are co-formed in the sublayer creating a homogenous composition having the desired Me¹Oxide:M²Oxide ratio. FIG. 11 shows and exploded view of the sublayers making up a stratum of the graded laminate, when such sublayers are homogenous.

In this version of the process, the strata are prepared by the co-deposition of the Me¹Oxide and Me²Oxide using an ALD process that includes simultaneous exposure of the reaction surface to at least two different precursors.

In addition, it should be appreciated that the graded laminate layer can contain more than two components in a compositional gradient in various embodiments. For example, one may prepare a 3-component gradient layer having Me¹Ox, Me²Ox and Me³Ox. If, for purposes of example, 1=Al, 2=Y and 3=Zr), the layer's sequence may be as follows:

If the underlying layer is Al₂O₃ (Me¹Ox), the sequence above continues with the following unit: CGL(Me¹Ox, Me²Ox)-Me²Ox-CGL(Me²Ox, Me³Ox)-Me³Ox-CGL(Me³Ox, Me¹Ox)-Me¹Ox (where “CGL” stands for compositional gradient layer).

By way of example, one may prepare a 4-component graded laminate layer having Me¹Ox, Me²Ox, Me³Ox and Me⁴Ox. In an example, 1=Al, 2=Y, 3=Zr and 4=Er and the graded laminate layer has the following sequence:

If the underlying layer is Al₂O₃ (Me¹Ox), the sequence above continues with the following unit: CGL(Me¹Ox, Me²Ox)-Me²Ox-CGL(Me²Ox, Me³Ox)-Me³Ox-CGL(Me³Ox, Me⁴Ox)-Me⁴Ox-CGL(Me⁴Ox, Me¹Ox)-Me¹Ox.

As in all of the graded laminate layers disclosed herein, the first oxide to be mentioned starts rich and ends poor, while the second oxide to be mentioned starts poor and ends up rich.

Once the graded laminate layer is completed, an external layer is deposited. Retuning to FIG. 2, an external layer of Me²Oxide may be deposited using an ALD process. See FIG. 2, box 58. This external layer may be composed of any number of monolayers; preferred may be about 1 to about 1000, about 300 to about 700 or about 400 to about 550 monolayers.

In an embodiment, this external layer can be followed by the deposition of a second graded laminate layer identical to that described above except for the compositional gradient between Me²Oxide and Me¹Oxide is reversed. See, FIG. 2, box 60.

This second graded laminate layer may be followed by deposition of an additional layer, preferably by an ALD process, composed of 100 mol % Me²Oxide, see FIG. 2, box 62, followed by a third graded laminate layer that that has a composition gradient identical to that of the first graded laminate, described infra. See FIG. 2, box 64.

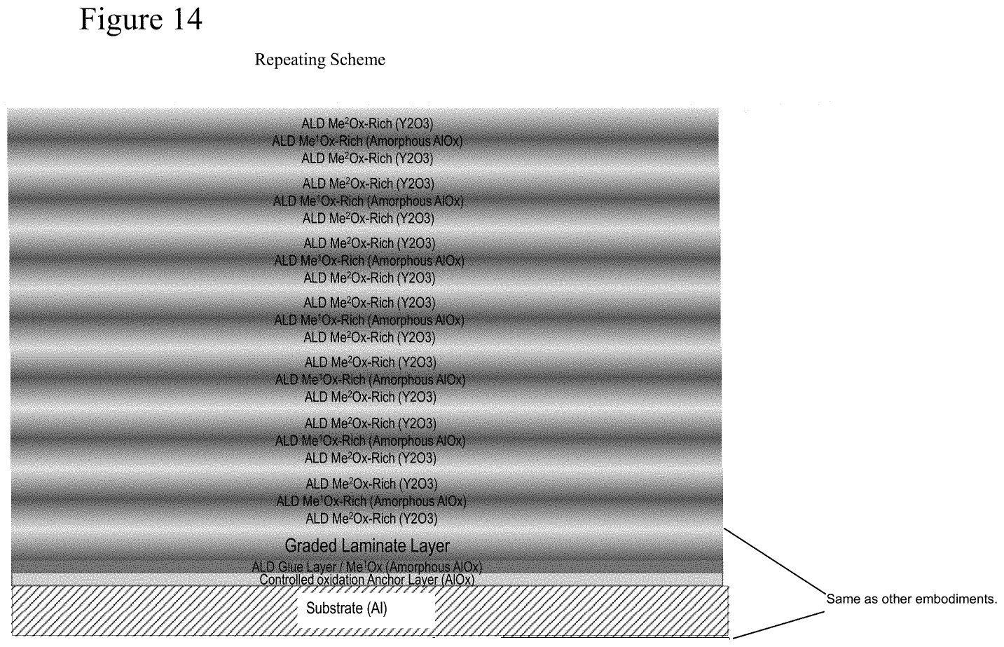

With reference to FIG. 14, in an alternative embodiment, the graded laminate layer may be continuously repeated, i.e., deposited sequentially on itself with no significant intervening pure layers to create a continuously cycled graded laminate structure without growing any significant thickness of any 100% pure metal oxide. Such layer would therefore have an overall structure shown below:

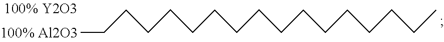 [SMILES: CCCCCCCCCCCCCCCCC]

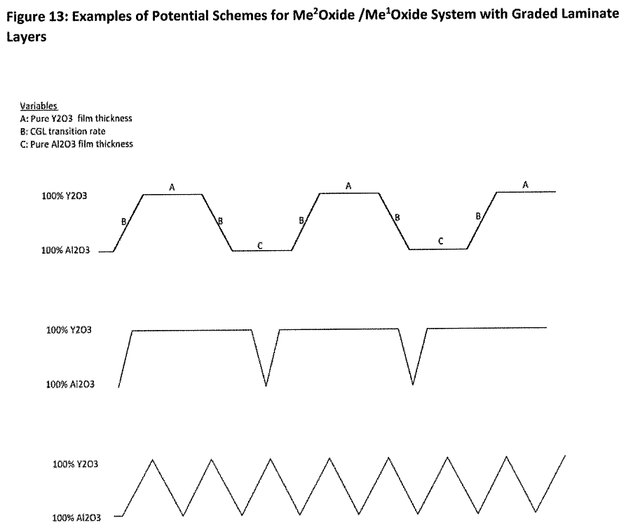

In such arrangement, the slope of the lines forming the peaks/valleys will vary depending on the steepness or mildness of the gradient with the layer. See also, FIG. 13.

With reference to the FIG. 14, on the glue layer is deposited a Me²Ox rich layer, which is followed by a Me¹Ox rich layer, which in turn is followed by a subsequent Me²Ox rich layer. Each of the successive layers may be formed independently by any of the methods described herein and may independently contain gradients of varying steepness or mildness as is desired for the end product.

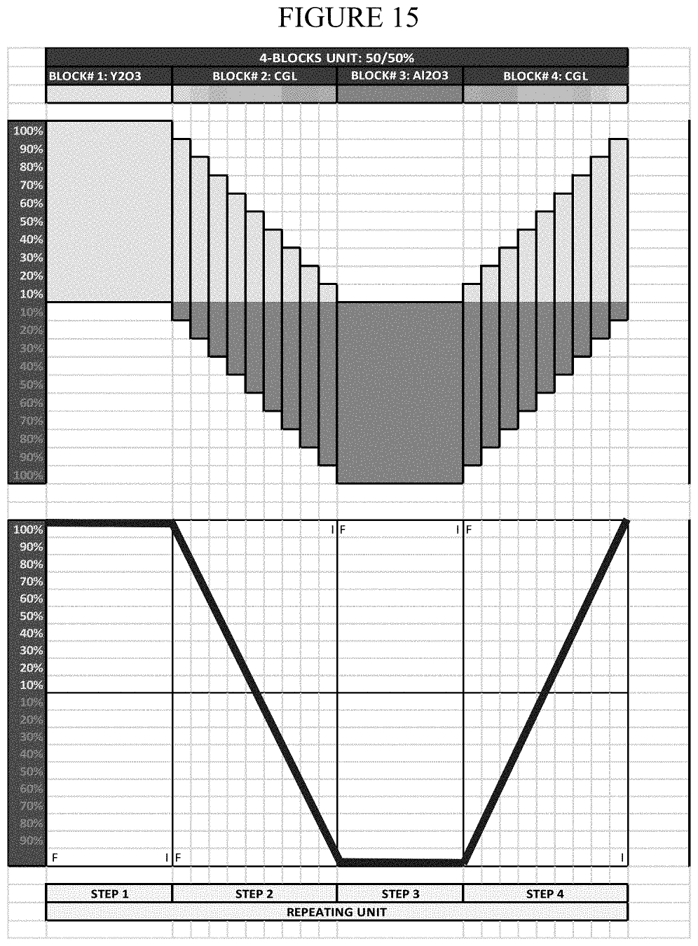

With reference to FIG. 15, when making a layer/film having a two component composition, an exemplary layer/film structure may be a layer/film composed of a unit of four “blocks”, where a “block” is a series of monolayers that differs compositionally from the “block” deposited prior to it. Beginning at the substrate and moving outwards: the first block is Y₂O₃, the second block is a graded block containing Y₂O₃/AlOx, the third block is AlOx, and the fourth block is a graded block containing AlOx/Y₂O₃. This exemplary layer and its compositional structure are represented graphically in FIG. 15. It has been found that this embodiment of the layer of the invention provides a high degree of homogeneity for the layer overall, resulting in resistance to delamination, to scratching, and to mechanical stressors. A more specific version of this embodiment is set out in Example 2, herein.

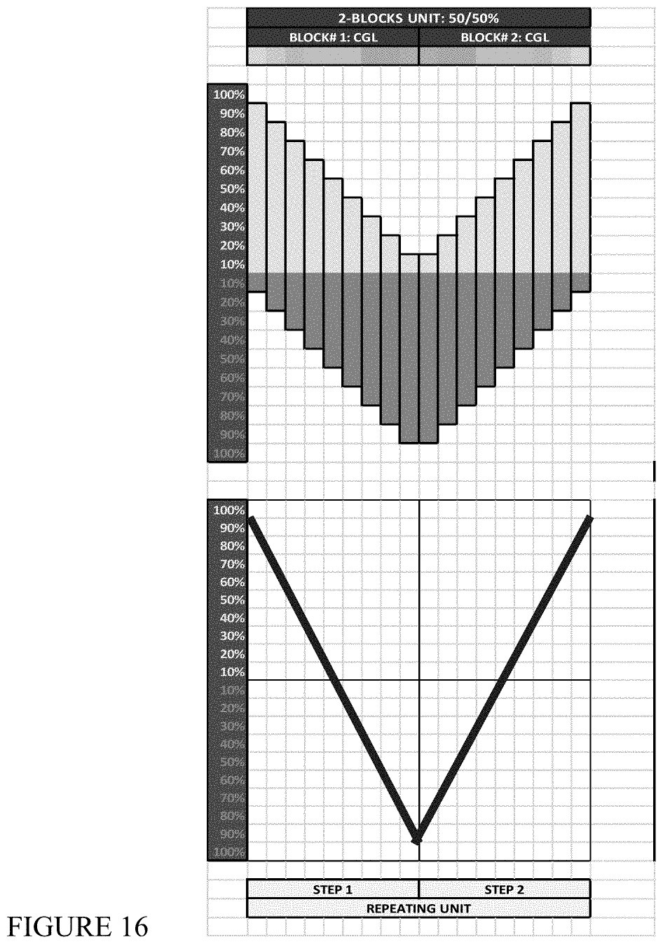

With reference to FIG. 16, when preparing another embodiment of the film/layer having a two component composition, an exemplary layer/film structure may be a layer/film composed of units of 2 blocks each, where each block is a compositionally graded block of 50%/50% Y₂O₃/AlOx, as shown in FIG. 16 where this exemplary layer and its compositional structure are represented graphically. It has been found that this embodiment is well suited when one desires a two-component film/layer that is thick and highly homogenous. If one of the components is amorphous, a 100% amorphous formulation can be created. In such instances, it may be preferred that the step size (i.e., size of each block, see FIG. 16) is large, for example, 15-20% of the total layer/film. Alternatively, if crystalline domains are desired, a small step size is recommended, for example, 1 to 10% of the total layer/film. The blocks may be engineered to be thinner or thicker, depending on the step size selected for the increment/decrement.

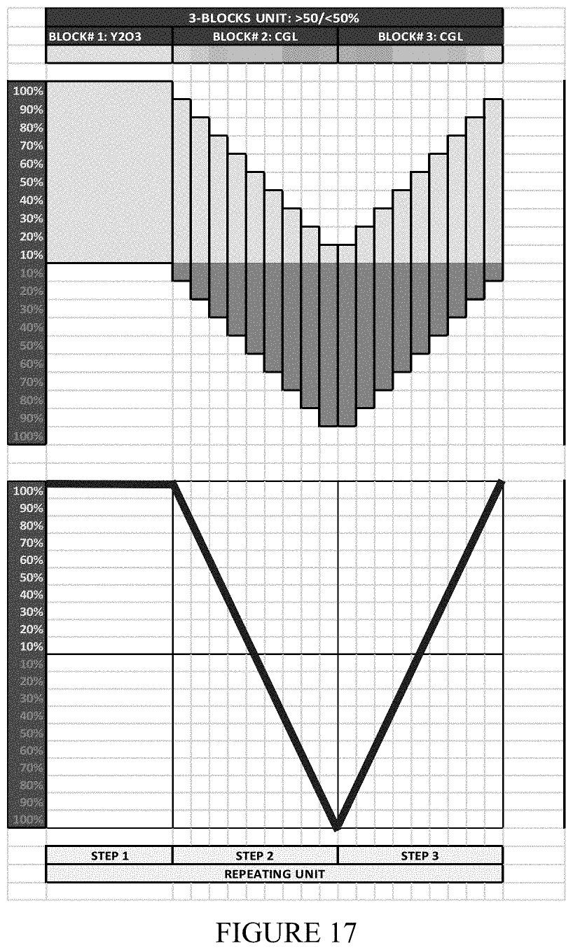

Referencing FIG. 17, an example of preparing another embodiment of the invention having interrupt layers is provided having units made up of three blocks, where the first block is a pure material, and the second and third blocks are each compositionally graded (“CGL”) blocks (50%/50%) having the structure as shown in FIG. 17 and serving as interrupt layers. In this embodiment, it may be preferred that the two CGL blocks are thin relative to the thickness of the pure material block, e.g., the CGL block(s) are about 10% to 50% of the thickness of the pure block. In this embodiment, the role of the CGL blocks is to interrupt the individual crystallite growth that over time leads to increased surface roughness. Thus, an application for this formulation is that of interrupt layer for thick mono-component films.

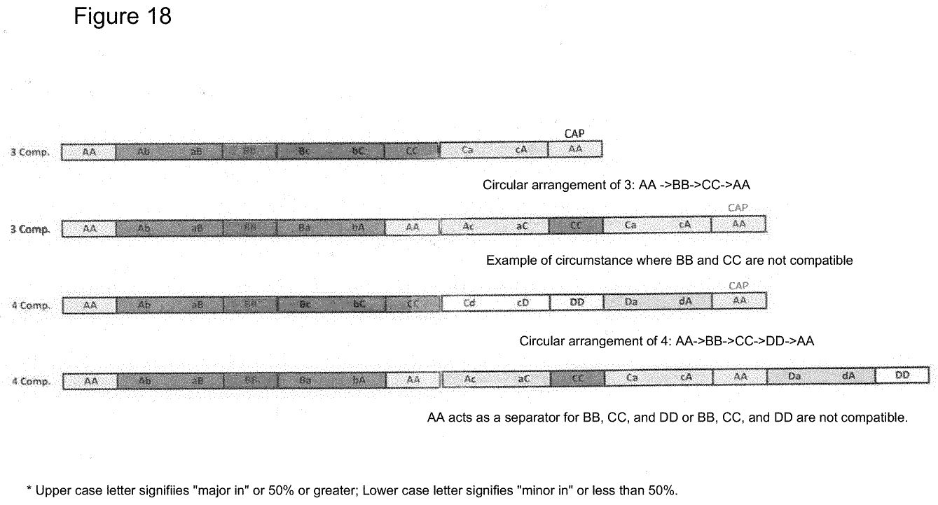

FIG. 18 provides examples of potential component arrangements of the compositional gradient blocks included in the invention when the blocks include three or four components. For example, when the Y/Al CGL ratio is 90/10, the sequence may be: Y₂O₃/Y₂O₃/Y₂O₃/Y₂O₃/Y₂O₃/AlOx/Y₂O₃/Y₂O₃/Y₂O₃/Y₂O₃. For a 50/50 Y/Al ratio the sequence may be: Y₂O₃/AlOx/Y₂O₃/AlOx/Y₂O₃/AlOx/Y₂O₃/AlOx/Y₂O₃/AlOx.

In an embodiment, a layer of the invention that is a laminate of Y₂O₃ and HfO₂, may be prepared on a nickel substrate. An anchor layer of NiO is grown in situ on the surface of the substrate via oxidation by ozone or another oxidizer. A glue layer of NiO is deposited by ALD on the anchor layer. The 3rd step is a CGL that makes the transition from NiO to Y₂O₃ (or the other oxide HfO₂, depending which one choose to start the film). The NiO/Y₂O₃ CGL starts NiO-rich and Y₂O₃-poor and ends up NiO-poor and Y₂O₃-rich. The 4th step is ALD deposition of a Y₂O₃ block. The 5th step is a CGL that starts Y₂O₃-rich and HfO₂-poor and ends up Y₂O₃-poor and HfO₂-rich. The 6th step is the ALD deposition of a HfO₂ block. The 7th step is a CGL that is non-superimposable and the mirror image of the CGL in step 5. The 8th step is the same as step number 4, so a cycle of steps 4 through 7 builds up the main structure of the film.

Alternatively in another embodiment, the invention includes a method of preventing, suppressing or eliminating the formation or growth of crystalline structure in an amorphous first metal oxide (Me¹Oxide) coating, or it can be used for preventing, suppressing or eliminating the unwanted growth phase or structure in a crystalline oxide single phase. Another use is to force an amorphous structure in an otherwise thermodynamically and kinetically stable crystalline metal oxide. As is known in the art, certain oxides, such as for example yttrium oxide, have a tendency to switch from cubic phase growth to monoclinic phase growth as it is being deposited to form a film or coating. Also, for the thermodynamically stable cubic phase of yttrium oxide, undesired columnar growth can become after a certain large enough thickness is achieved.

These behaviors can limit one's ability to prepare a uniform successful film of a greater thickness. The inventive process provides an interrupt layer which is disposed intermittently between the desired Me²Oxide coating layers. Implementation of this process permits suppression or elimination of the growth or transition of a second metal oxide in a coating from desired amorphous form to the thermodynamically stable monocrystalline form, even as the temperature the film is subjected, is ramped up.

In an embodiment of this method, Me¹Oxide and Me²Oxide are not the same and may be, for example, Y₂O₃, Al₂O₃ or any of the other oxide options using any of the precursors in any combination detailed above.

The interrupt layer in this embodiment of the invention includes at least three interrupt sublayers, each of which is deposited, one on the other, in the sequence described herein. Preferably an atomic layer deposition process is used to lay down each sublayer.

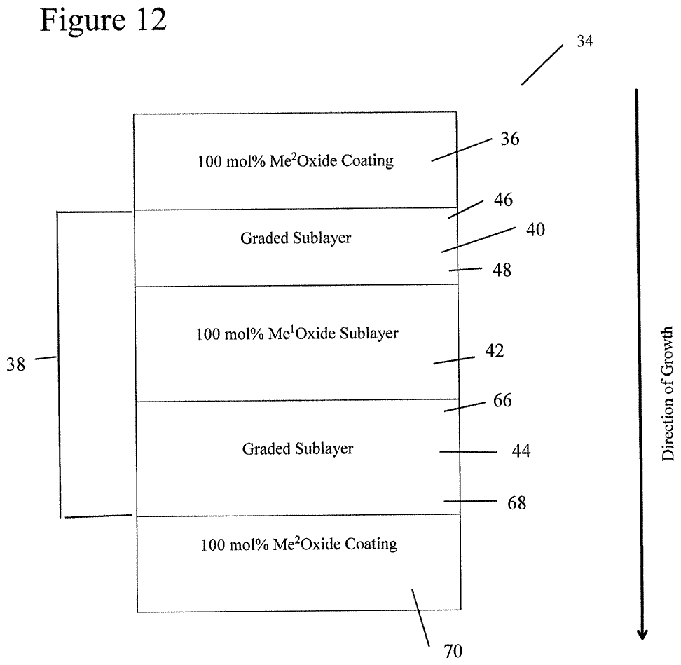

With reference to FIG. 12, in preparation of a film or coating 34, when the initially-deposited Me²Oxide layer 36 reaches a critical thickness of typically between 1-1000 nm where it may have a tendency to transition from an amorphous to crystalline form or from one crystalline phase to another, or there is a change in the morphology of the crystalline phase, the interrupt layer 38 is deposited. The three sublayers of the interrupt layer 38 are:

(i) A first interrupt sublayer 40 that is a graded laminate sublayer, prepared in the manner described supra with respect to the graded laminate layers. The graded laminate sublayer 40 of this embodiment contains each of Me¹Oxide and Me²Oxide in a gradient with an increasing content of the first metal oxide (Me¹Oxide) and a decreasing content of the second metal oxide (Me²Oxide) such that a lowermost stratum 46 of the first graded layer immediately adjacent to the first Me²Oxide coating layer 36 contains no more than about 0.1 mol % to about 49 mol % of the first metal oxide (Me¹Oxide). Conversely, an uppermost stratum 48 of the first graded laminate sublayer 40 that is immediately adjacent to a second sublayer 42 contains no more than about 0.1 mol % to about 49 mol % of the second metal oxide (Me²Oxide).

(ii) A second interrupt sublayer 42 containing Me¹Oxide in an amount of about 100 mol %.

(iii) A third interrupt sublayer 44 that is a graded laminate sublayer containing Me¹Oxide and Me²Oxide. The third interrupt sublayer 44 has a gradient with an increasing content of the second metal oxide (Me²Oxide) and a decreasing content of the first metal oxide (Me¹Oxide) such that a lowermost stratum 66 of the third interrupt layer that is immediately adjacent to the second sublayer layer contains no more than about 0.1 mol % to about 49 mol % of the second metal oxide (Me²Oxide). Conversely, an uppermost stratum 68 of the third interrupt sublayer 44 that is immediately adjacent to a second Me²Oxide coating layer 70 contains no more than about 0.1 mol % to about 49 mol % of the first metal oxide (Me¹Oxide).

Deposited on this 3-part interrupt layer 38 is second Me²Oxide coating layer 70 that is preferable 100 mol % Me²Oxide. This sequence may be repeated an infinitum until a desired thickness of the Me²Oxide-based coating is achieved.

Because the graded laminate layers (and sublayers) are formed as laminates using “stacked” strata the invention allows for great flexibility with respect to the rate of transition for the graded layers or sublayers, which in turn provides for the production of an infinite variety of coatings with varying physical and chemical properties. FIG. 13 provides a linear illustration of the potential transition gradients that can be produced within the coatings of the invention.

Also included within the scope of the invention are any coatings prepared by any of the methods described supra, substrates and/or components that bear multi-layer coatings prepared by any of the methods described supra, equipment or devices that contain any of such components and/or multi-layer coatings.

### EXAMPLES

### Example 1—Preparation of an Anchor Layer

An in situ layer of AlOx was grown out of the freshly cleaned surface of an aluminum substrate, by oxidation with ozone in a in a standard cross-flow type ALD reactor as follows.

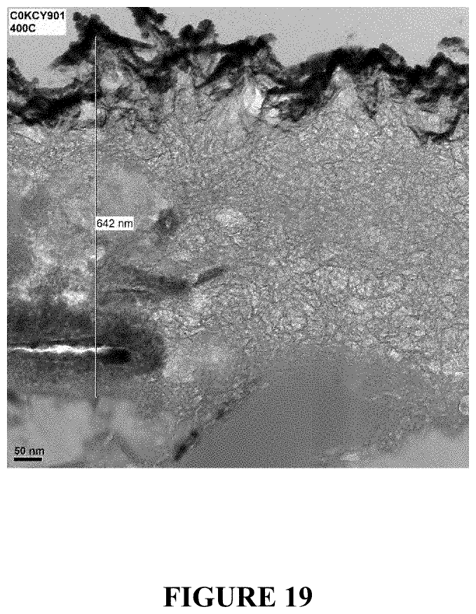

An aluminum substrate of a one inch diameter and 0.25 inches thick was placed in a reactor chamber. The chamber had a temperature of 400 degrees C. and the pressure inside the reactor was at 0.4 hPa. A mixture of 19% ozone in oxygen was delivered into the chamber at a flow rate of 150 sccm. The process employed 400 cycles of ozone pulsing for 2 seconds and purging for 18 seconds. The resulting AlOₓ anchor layer grown was approximately 640 nm thick. A micrograph of the resulting anchor layer in cross section is shown in FIG. 19. FIG. 19 shows the aluminum substrate and the anchor layer of a thickness of about 400 to 600 nanometers.

### Example 2—Development of a Compositional Gradient Coatings With Four “Blocks” and Cap

This example provides a illustrative process to prepare a “classic”, “generic” composition gradient layer film for two component compositions. Use of the CGL blocks ensures an improved interface and transition between the pure blocks of the two different materials. The formulation is predicted to offer a high degree of homogeneity for the 2 Component Laminate films, with direct outcome in the form of maximum resistance to delamination, scratching, mechanical stress testing, etc.

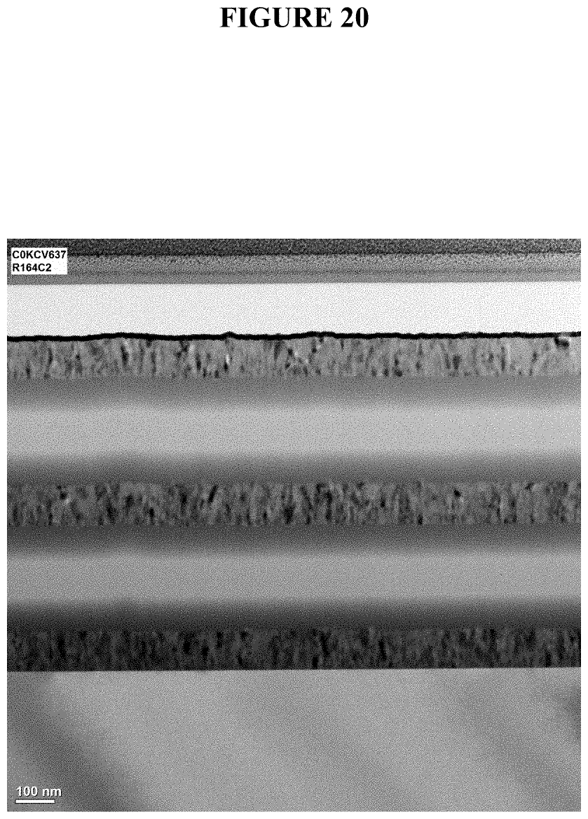

A 850 nm Y₂O₃/AlOₓ plasma etch-resistant film having two units or layers, each consisting of four blocks or monolayers and terminated with a capping block/monolayer of Y₂O₃ was formed on the surface of a silicon substrate as shown in FIGS. 20 to 24 in a standard cross-flow type ALD reactor.

A 200 mm silicon wafer substrate was placed into a reaction chamber of an ALD reactor. The reactor was then pumped down with a vacuum pump while purging with nitrogen to a pressure of 0.4 hPa. The temperature of the reaction chamber was set to 250 degrees C. The flow rates through the delivery lines were all 150 sccm.

Y₂O₃ was deposited using tris-(methylcyclopentadienyl) yttrium precursor and water as the co-reactant. The yttrium precursor was heated to 145 degrees C. and water cooled to 22 degrees C. The pulsing sequence for the Y₂O₃ layers was deposited as follows: (a) A 2 second yttrium precursor vapor pulse followed by nitrogen purge step of 12 seconds followed by a 0.1 second water vapor pulse followed by a second nitrogen purge step of 18 seconds. This sequence of steps was repeated for 600 cycles to build up a 100 nm thick layer of Y₂O₃.

Y₂O₃ was used to create the YAₗOₓ CGL blocks along with AlOₓ employing the same pulsing parameters described above.

AlOₓ was deposited using trimethyl aluminum (TMA) precursor and water as the co-reactant. The TMA precursor was cooled to 22 deg. C and water cooled to 22 deg. C. The pulsing sequence for AlOₓ was as follows: a 0.3 second TMA precursor vapor pulse followed by nitrogen purge step of 12 seconds followed by a 0.2 second water vapor pulse followed by a second nitrogen purge step of 18 seconds. This sequence of steps was repeated for 1,000 cycles to build the 110 nm block.

AlOₓ was used to create the YAₗOₓ CGL blocks along with Y₂O₃ employed the same pulsing parameters described above. The structure of the film is described below.

The first layer deposited on to the silicon wafer was 250 nm of pure Y₂O₃. Next, a CGL YAₗOₓ layer was formed by combining the Y₂O₃ and AlOₓ pulsing schemes described above in varying ratios. The first layer of the YAₗOₓ layer deposited on the initial pure Y₂O₃ layer started with a ratio of nine Y₂O₃ cycles to one AlOₓ cycle for a total of 10 cycles.

Next the Y₂O₃/AlOₓ ratio was changed to 8:2, respectively, for a total of 10 cycles. This trend in the sequence then continued until the ratio was 1:9.

This then was followed by a third layer consisting of 110 nm layer of pure AlOx. The fourth layer was a CGL YAₗOₓ layer and this started with a ratio of nine AlOₓ cycles to one Y₂O₃ cycle, for a total of 10 cycles. Next the AlOₓ/Y₂O₃ ratio was changed to 8:2, respectively, for a total of 10 cycles. This trend in the sequence then continued until the ratio was 1:9. This sequence of four steps was repeated twice and then a 100 nm capping layer of pure Y₂O₃ terminated the film.

The resulting film and aspects of the film are shown in FIGS. 20 to 24. FIG. 20 is a micrograph of the cross section of the coating of Example 2 generated by energy dispersive X-ray spectrometry (EDS) techniques. Deposited on a silicon wafer substrate, the coating includes a first layer that is composed of a repeating four block unit (from the substrate upwards: a Y₂O₃ block, a CGL 1 block, a AlOₓ block, and a CGL2 block). A second layer is deposited on the layer; it is composed of a repeating four block unit (from first layer upwards: a Y₂O₃ block, a CGL 1 block, an AlOₓ block, and a CGL2 block). The second layer is capped with a Y₂O₃ capping block. The two CGL blocks and make a transition between the blocks of pure metal oxides. The two CGL blocks are non-superimposable and mirror images of each other.

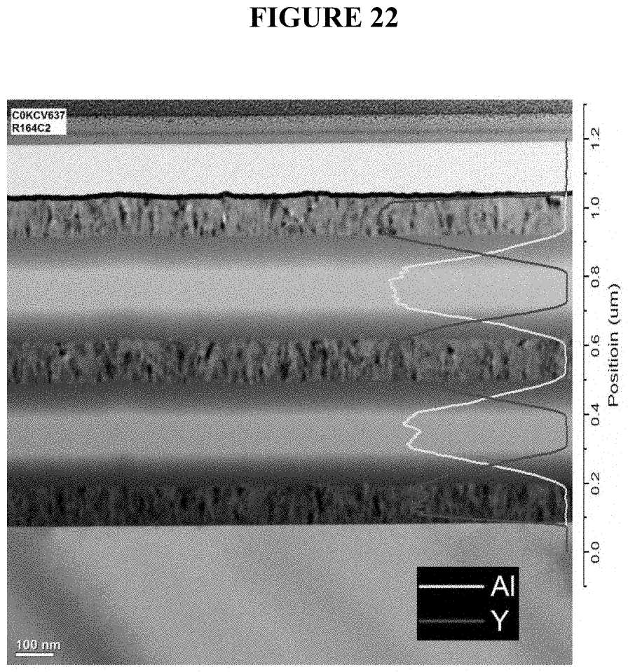

FIG. 22 shows cross section EDS line scan data of elemental aluminum and yttrium as a function of the position with the layer from the silicon substrate exhibiting intermixing of Y₂O₃ and AlOx in the graded layers.

FIG. 22 is a micrograph prepared by transmission electron microscopy (TEM) of the coating grown in Example 2 with the EDS line scan data overlaid.

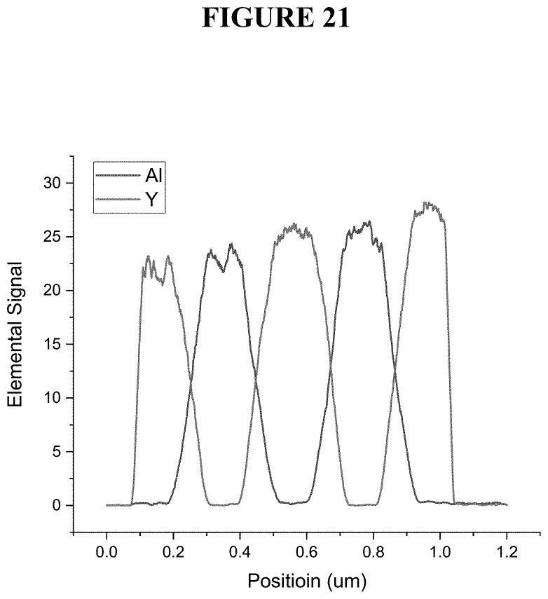

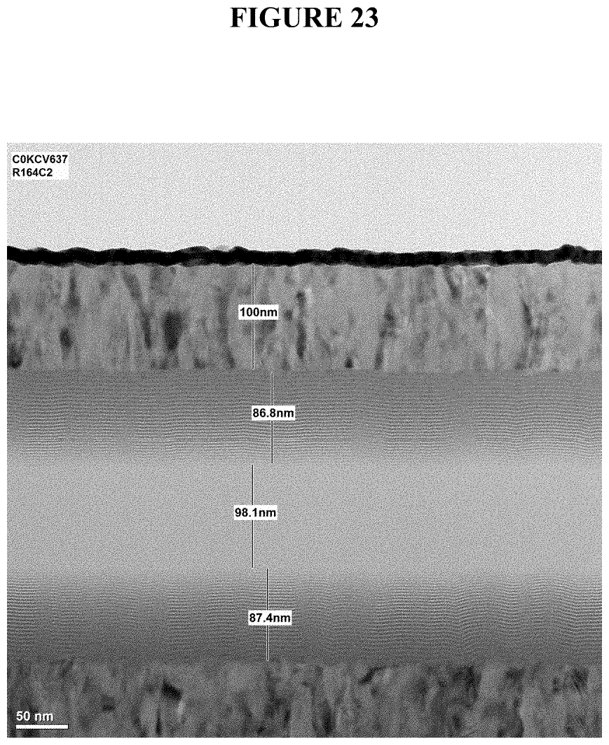

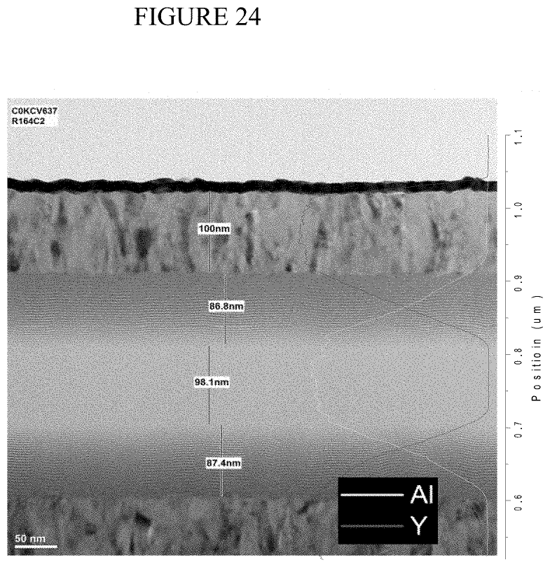

FIGS. 23 and 24 are “zoomed in” versions of the TEM cross section micrograph of FIG. 22 (without substrate) providing a view of the Y₂O₃/AlOx coating structure where one can observe the graded laminate interlayers that are used to transition between Y₂O₃ and AlOx. The micrograph of FIG. 21 has the EDS line scan overlaid.

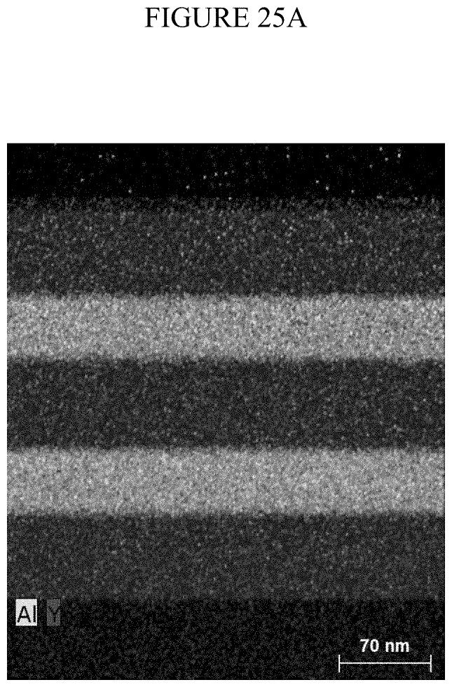

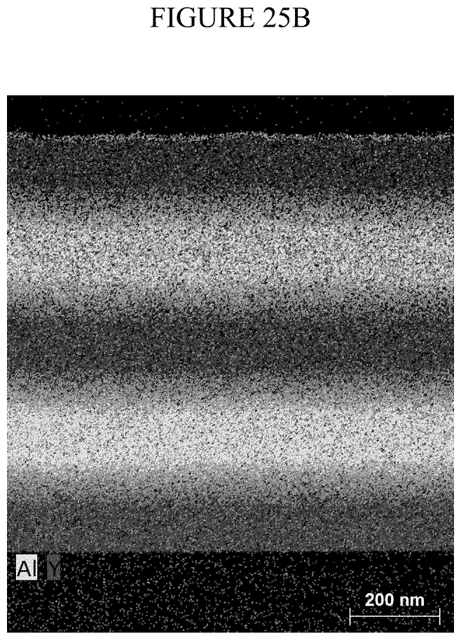

FIGS. 25A and 51B are EDS “color maps” of the micrographs of the coating in cross section. FIG. 25A shows an exemplary coating with more rapidly transitioning CGL interlayers (appearing as the relatively discrete orange bands). FIG. 25B shows an exemplary coating with a more gradual CGL transition (appearing as the relatively fuzzy orange bands).

### Example 3—Using the CGL as an “Interrupt” Layer

A 1.1 um Y₂O₃ plasma etch-resistant film with three interrupt layers was formed on the surface of a silicon substrate shown in a standard crossflow type ALD reactor.

To accomplish this, a 200 mm silicon wafer substrate was placed into a reaction chamber of an ALD reactor. The reactor was then pumped down with a vacuum pump while purging with nitrogen to a pressure of 0.4 hPa. The temperature of the reaction chamber was set to 250 deg. C. The flow rates through the delivery lines were all 150 sccm.

Y₂O₃ was deposited using tris(methylcyclopentadienyl)yttrium precursor and water as the co-reactant. The yttrium precursor was heated to 145 deg. C. and water cooled to 22 degrees C. The pulsing sequence for the Y₂O₃ was as follows: A 2 second yttrium precursor vapor pulse followed by nitrogen purge step of 12 seconds followed by a 0.1 second water vapor pulse followed by a second nitrogen purge step of 18 seconds. This sequence of steps was repeated for 1440 cycles to build up a 255 nm thick layer of Y₂O₃.

Y₂O₃ was used to create the YAlOx CGL interrupt layers along with AlOx employing the same pulsing parameters described above.

AlOx was used to create the YAlOx CGL interrupt layers; it was deposited using trimethyl aluminum (TMA) precursor and water as the co-reactant. The TMA precursor was cooled to 22 degrees C. and water cooled to 22 deg. C. The pulsing sequence for AlOx was as follows: a 0.3 second TMA precursor vapor pulse followed by nitrogen purge step of 12 seconds followed by a 0.2 second water vapor pulse followed by a second nitrogen purge step of 18 seconds. This sequence of steps was used to build the CGL interrupt layer described below.

The first layer deposited on to the silicon wafer was 250 nm of pure Y₂O₃. Next, a CGL YAlOx interrupt layer was formed by combining the Y₂O₃ and AlOx pulsing schemes described above in varying ratios.

The first sublayer of the YAlOx interrupt layer deposited on the initial pure Y₂O₃ layer started with a ratio of nine Y₂O₃ cycles to 1 AlOx cycle for a total of 10 cycles. Next the Y₂O₃/AlOx ratio was changed to 8:2, respectively, for a total of 10 cycles. This trend in the sequence then continued until the ratio was 1:9, respectively, at which point the scheme was reversed until the Y₂O₃/AlOx ratio reached 9:1, respectively, again. The reversal of the sequence starts a second sublayer of the YAlOx interrupt layer, and this is the mirror image of the first sublayer of the CGL YAlOx interrupt layer. This then was followed by another 250 nm layer of Y₂O₃. The YAlOx interrupt layer followed by 250 nm pure Y₂O₃ layer was repeated 2 more times to build a 1 um film stack.

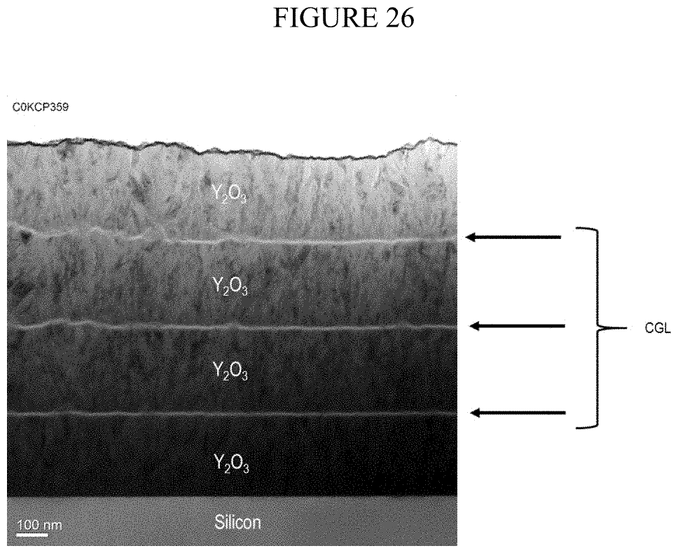

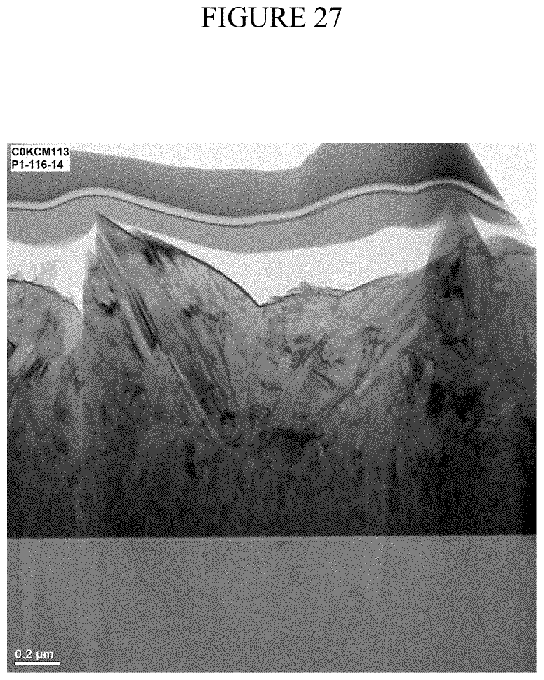

A micrograph of a cross section of the resultant coating is shown in FIG. 26. As described above, the coating was grown on a silicon substrate and includes four pure Y₂O₃ layers, and three graded “interrupt” layers. Use of the graded interrupt layers provides better uniformity to the Y₂O₃ structure (see FIG. 27) and better adhesion of the coating overall.

FIG. 31 is a micrograph of a cross section of a coating formed for comparison of Y₂O₃ without the interrupt layers. The increased disorderliness of the Y₂O₃ crystal growth as the coating progress is readily apparent.

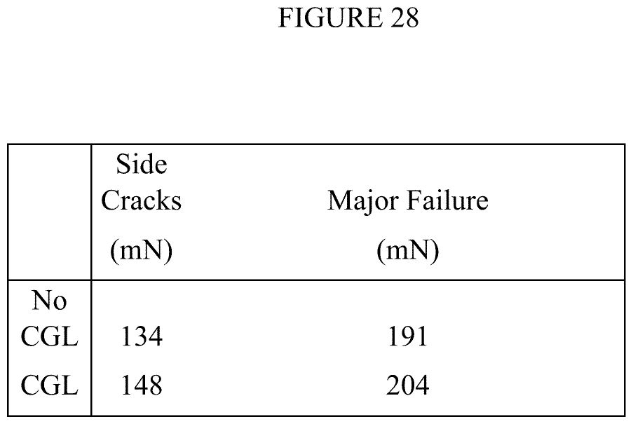

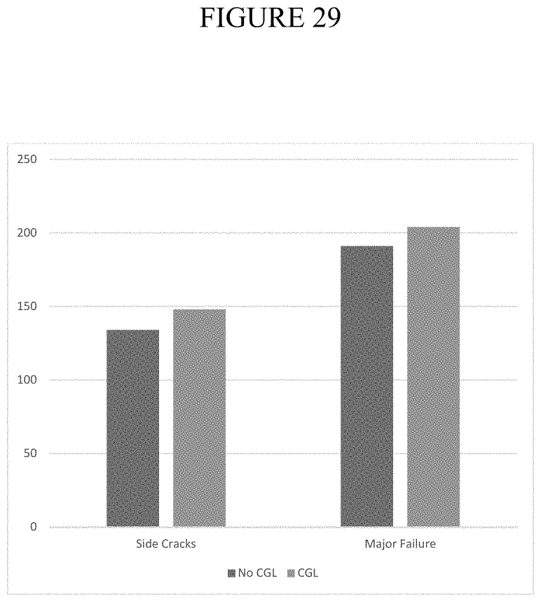

FIG. 28 and FIG. 29 demonstrate the improved adhesion obtained by the use of CGL interrupt method over using abrupt transitions to transition from one material to another. FIG. 28 is a table showing data obtained from scratch adhesion test results for a 1 micrometer Y₂O₃ coating deposited with four interrupt layers of AlOx every 200 nm with (“CGL) and without (“no CGL”) use of the inventive methods. Scratch adhesion testing was performed using guidance, recommendations and general procedures from ASTM standards (G171, C1624, D7187). FIG. 29 is a bar graph comparing occurrences of side cracking and major failures of each of an exemplary coating of the invention (dark bars) and a coating prepared without the interrupt layers (lighter bars).

### Example 4—Exemplary Coating

An exemplary coating of the invention was created containing an anchor layer, a glue layer, an AlOx+CGL layer and final yttrium-aluminum oxide overlay. First, an in situ layer of AlOx was grown out of the freshly cleaned surface of an aluminum substrate as described in Example 1 herein.

Next the reaction chamber was cooled to 250° C. and a 40 nm layer of aluminum oxide (AlOx) was deposited using 400 ALD cycles to form a strong adhesion layer (glue layer) for the rest of the film. The AlOx glue layer was deposited at 250° C. with tri-methylaluminum (TMA) and water by ALD. The glue layer film becomes part of the substrate on which the rest of the film is deposited.

Following deposition of the AlOx glue layer, a CGL YAlOx interrupt layer was formed by combining the Y₂O₃ and AlOx pulsing schemes as described in previous examples in varying ratios. The first layer of the YAlOx layer deposited on the initial pure AlOx glue layer started with a ratio of twenty-nine AlOx cycles to one Y₂O₃ cycle. The next layer was deposited with twenty-eight cycles of AlOx and two cycles of Y₂O₃. This trend continued until an AlOx/Y₂O₃ cycle ratio of 1 to 29 was reached.

Next a 20 nm layer of Y₂O₃ was deposited using parameters described in Examples 2 & 3. This was followed by a 16 nm CGL layer was used to transition from 100% Y₂O₃ to a mixed Y/Al oxide. Finally, a generic 820 nm yttrium-aluminum oxide film was grown on top.

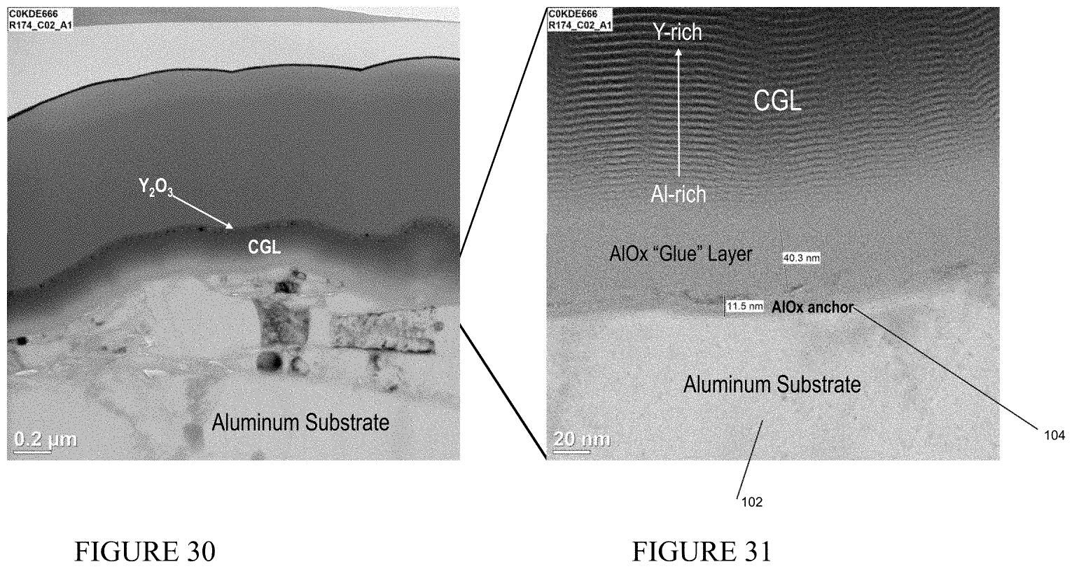

FIG. 30 is a TEM micrograph of a cross section of the coating on substrate prepared as described above. FIG. 31 is a “blow up” of a portion of the cross-sectioned coating showing the aluminum substrate with aluminum oxide “anchor” layer, 40 nm AlOx “glue” layer, 170 nm CGL layer, 16 nm Y₂O₃ layer, 16 nm CGL layer, and amorphous 820 nm top YAlOx test film.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

What is claimed is:

1. A method of providing a multi-layer coating to a surface of a substrate comprising:
a) forming an anchor layer by controlled oxidation of the surface of the substrate;
b) depositing on the anchor layer a glue layer comprising an amorphous or crystalline first metal oxide (Me¹Oxide);
c) forming on the glue layer a graded laminate layer
containing the first metal oxide (Me'Oxide) and a second metal oxide (Me²Oxide), and
having a gradient with an increasing content of the second metal oxide (Me²Oxide) and a decreasing content of the first metal oxide (Me¹Oxide) such that
a lowermost stratum of the graded laminate layer immediately adjacent to the glue layer contains no more than about 0.1 mol % to about 49 mol % of the second metal oxide (Me²Oxide) and
an uppermost stratum of the graded laminate layer immediately adjacent to an external layer contains no more than about 0.1 mol % to about 49 mol % of the first metal oxide (Me¹Oxide); and
d) depositing on the graded laminate layer the external layer comprising the second metal oxide (Me²Oxide).

2. The method of claim 1 wherein each of the anchor layer, the glue layer, the graded laminate layer and/or the external layer is independently formed and/or deposited using an atomic layer deposition process.

3. The method of claim 1 wherein the glue layer is 100 mol % Me¹Oxide and the external layer is 100 mol % Me²Oxide.

4. The process of claim 1 further comprising
e) depositing on the external layer a second graded laminate layer
containing the second metal oxide (Me²Oxide) and the first metal oxide (Me¹Oxide) and
having an increasing content of the first metal oxide (Me¹Oxide) and a decreasing content of the second metal oxide (Me²Oxide) such that
a lowermost stratum of the second graded laminate layer immediately adjacent to the external layer contains no more than about 0.1 mol % to about 49 mol % of the first metal oxide (Me¹Oxide) and
an uppermost stratum of the second graded laminate layer immediately adjacent to a second external layer contains no more than about 0.1 mol % to about 49 mol % of the second metal oxide (Me²Oxide); and
f) depositing on the second graded laminate layer the second external layer comprising the first metal oxide (Me¹Oxide).
g) depositing on the first metal oxide (Me¹Oxide) a graded laminate layer
containing the first metal oxide (Me¹Oxide) and a second metal oxide (Me²Oxide), and
having a gradient with an increasing content of the second metal oxide (Me²Oxide) and a decreasing content of the first metal oxide (Me¹Oxide) such that
a lowermost stratum of the graded laminate layer immediately adjacent to the glue layer contains no more than about 0.1 mol % to about 49 mol % of the second metal oxide (Me²Oxide) and
an uppermost stratum of the graded laminate layer immediately adjacent to an external layer contains no more than about 0.1 mol % to about 49 mol % of the first metal oxide (Me¹Oxide);

5. The method of claim 4 wherein steps (d), (e), (f) and (g) are sequentially repeated for 2 to 100 times.

6. The method of claim 1 wherein the graded laminate layer(s) further independently comprise at least one intermediate stratum disposed between the lowermost and the uppermost strata that is compositionally structured to maintain the gradient of the graded laminate layer.

7. The method of claim 1 wherein (Me¹Oxide) is Al₂O₃ and (Me²Oxide) is Y₂O₃.

8. The method of claim 1 wherein the substrate is selected from a non-ferrous metal, a non-ferrous metal alloy, a ferrous metal, and a ferrous metal alloy.

9. The method of claim 1 wherein the substrate is selected from titanium, aluminum, nickel, zinc, aluminum alloys, steels, stainless steel, carbon steel, alloy steel, copper, copper alloys, nickel alloys, ceramic, silicon, lead, and lead alloys.

10. The method of claim 1 wherein the substrate is a chamber component.

11. The method of claim 1 wherein the substrate is selected from a shower head, a chamber wall, a nozzle a plasma generation unit, a diffuser, a gas line interior, and a chamber orifice.

12. The method of claim 1 wherein the substrate is selected from a planar member and a 3D shape, a 3D shape with high aspect ratio features and a 3D shape with medium and low aspect ratio features.

13. The method of claim 1 wherein the anchor layer is formed by anodization of the surface of the substrate.

14. The method of claim 1 wherein the anchor layer is formed by exposure of the surface of the substrate by exposure to ozone, O₂, O₂-plasma, N₂O, NO, HOOH and/or mixtures thereof.

15. The method of claim 1 wherein the anchor layer has a thickness of about 0.1 to about 100 nanometers.

16. The method of claim 1 wherein the anchor layer has a thickness selected from thicknesses of about 1 to about 50 nanometers, about 5 to about 35 nanometers and about 10 to about 20 manometers.

17. The method of claim 1 wherein the glue layer is composed of about 2 to about 1000 monolayers, wherein each monolayer is deposited by an atomic layer deposition process.

18. The method of claim 1 wherein the first metal oxide (Me¹Oxide) is selected from an oxide of one of hafnium, yttrium, a lanthanide series element, zirconium and mixtures of the same.

19. The method of claim 1 wherein the first metal oxide (Me¹Oxide) is selected from alumina, Rare Earth Oxides, binary, ternary or quaternary metal oxides containing at least one rare earth metal, Y₂O, La₂O₃, HfO₂, Ta2O₅, Er₂O, ZrO₂, Y₃Al₅O₁₂ (YAG), Er₃Al₅O₁₃ (EAG), Y₄Al₂O₉ (YAM), YAlO₃ (YAP), Er₄Al₂O₉ (EAM), ErAlO₃ (EAP) and mixtures thereof.

20. The method of claim 1 wherein a thickness of the glue layer is selected from thickness of about 0.1 to about 100 nanometers and about 100 nanometers to about 1000 nanometers.

21. The method of claim 1 wherein a thickness of the glue layer is selected from thicknesses of about 1 to about 50 nanometers, about 5 to about 35 nanometers and about 10 to about 20 manometers.

22. The method of claim 1 wherein the first metal oxide (Me¹Oxide) and the second metal oxide (Me²Oxide) are not the same.

23. The method of claim 1 wherein the second metal oxide (Me²Oxide) is selected from an oxide of one of yttrium, a lanthanide series element, hafnium, tantalum, zinc, titanium, zirconium and mixtures of the same.

24. The method of claim 1 wherein the first metal oxide is selected from alumina, silica, hafnia, zirconia, titania, Y₂O, Er₂O, ZrO₂, Y₃Al₅O₁₂ (YAG), Er₃Al₅O₁₃ (EAG), Y₄Al₂O₉ (YAM), YAlO₃ (YAP), Er₄Al₂O₉ (EAM), ErAlO₃ (EAP), HfO₂, ZrO₂, TaO₅, ZnO, TiO₂, and mixtures thereof.

25. The method of claim 1 wherein the lowermost stratum of the graded laminate layer immediately adjacent to the glue layer comprises no more than 1 mol % to 30 mol % of the second metal oxide and the uppermost stratum of the graded laminate layer immediately adjacent to an external layer comprises no more than 1 mol % to about 30 mol % of the first metal oxide.

26. The method of claim 1 wherein the lowermost stratum of the graded laminate layer immediately adjacent to the glue layer comprises no more than 5 mol % to 20 mol % of the second metal oxide and the uppermost stratum of the graded laminate layer immediately adjacent to an external layer comprises no more than 5 mol % to about 20 mol % of the first metal oxide.

27. The method of claim 1 wherein the grade layer is composed of at least three strata.

28. The method of claim 1, wherein the grade layer is composed of at least three strata and at least one stratum is composed of more than one monolayer, wherein each monolayer contains a single metal oxide and is a result of a cycle of an atomic layer deposition process.

29. The method of claim 1, wherein the grade layer is composed of at least three strata and at least one stratum is composed of more than one monolayer, wherein each monolayer is formed by co-depositing the first and the second metal oxides forming substantially compositionally homogenous monolayer.

30. A multi-layer coating prepared by the method of claim 1.

31. A component comprising the multi-layer coating of claim 30.

32. The component of claim 31 selected from the group consisting of semiconductor manufacturing equipment, flat panel display manufacturing equipment, a shower head, a chamber wall, a nozzle a plasma generation unit, a diffuser, a gas line interior, and a chamber orifice, chamber liner, chamber lid.

33. A method of suppressing or inhibiting growth of a certain phases and/or structures of a crystalline structure with an amorphous first metal oxide (Me¹Oxide) coating comprising:
a) depositing a second Me²Oxide coating layer containing Me²Oxide in an amount of about 100 mol % using an atomic layer deposition process;
b) depositing on the first layer an interrupt layer containing at least three sublayers deposited sequentially, one upon the next, using an atomic layer deposition process:
i) a first interrupt sublayer that is a graded laminate sublayer containing Me¹Oxide and Me²Oxide, wherein the first graded laminate sublayer has a gradient with an increasing content of the first metal oxide (Me¹Oxide) and a decreasing content of the second metal oxide (Me²Oxide) such that
a lowermost stratum of the first graded sublayer immediately adjacent to the second Me²Oxide coating layer contains no more than about 0.1 mol % to about 49 mol % of the first metal oxide (Me¹Oxide) and
an uppermost stratum of the first graded sublayer immediately adjacent to a second sublayer contains no more than about 0.1 mol % to about 49 mol % of the second metal oxide (Me²Oxide);
ii) a second interrupt sublayer containing Me¹Oxide in an amount of about 100 mol %; and
iii) a third interrupt sublayer that is a graded laminate layer containing Me¹Oxide and Me²Oxide wherein the second interrupt layer has a gradient with an increasing content of the second metal oxide (Me²Oxide) and a decreasing content of the first metal oxide (Me¹Oxide) such that
a lowermost stratum of the interrupt layer immediately adjacent to the second sublayer layer contains no more than about 0.1 mol % to about 49 mol % of the second metal oxide (Me²Oxide) and
an uppermost stratum of the interrupt layer immediately adjacent to a second Me²Oxide coating layer contains no more than about 0.1 mol % to about 49 mol % of the first metal oxide (Me¹Oxide); and
e) depositing on the interrupt layer a second Me²Oxide coating layer containing Me²Oxide in an amount of about 100 mol % using an atomic layer deposition process.

34. The method of claim 33 wherein the first metal oxide (Me¹Oxide) is Al₂O₃

35. The method of claim 34 wherein the second metal oxide (Me2Oxide) is Y₂O₃

36. The method of claim 33 wherein the interrupt layers further independently comprise at least one intermediate stratum disposed between the lowermost and uppermost strata that is compositionally structured to maintain the gradient of the interrupt layers.

37. A substrate having a surface bearing the coating of claim 33.

38. The substrate of claim 37 wherein the substrate is made of a material selected from a non-ferrous metal, a non-ferrous metal alloy, a ferrous metal and a ferrous metal alloy, quartz, a glass, a fiberglass, a polymer, titanium, aluminum, aluminum alloys, steels, stainless steel, carbon steel, alloy steel, copper, copper alloys, lead, and lead alloys.

39. The substrate of claim 37 wherein the substrate is a chamber component.

40. The substrate of claim 39 wherein the component is selected from a shower head, a chamber wall, a nozzle a plasma generation unit, a diffuser, a gas line interior, a chamber orifice.
